(19) United States
(12) Patent Application Publication
(10) Pub. No.: US 2021/0182454 A1
(43) Pub. Date: Jun. 17, 2021

(54) System and Methods for Autonomous Vehicle Testing with a Simulated Remote Operator

(71) Applicant: UATC, LLC, San Francisco, CA (US)

(72) Inventors: Michael Smaili, San Jose, CA (US); Sean Shanshi Chen, San Francisco, CA (US); Samann Ghorbanian-Matloob, San Francisco, CA (US); Vladimir Zaytsev, San Francisco, CA (US); Mark Yen, San Francisco, CA (US)

(21) Appl. No.: 16/853,084

(22) Filed: Apr. 20, 2020

Related U.S. Application Data
(60) Provisional application No. 62/946,718, filed on Dec. 11, 2019.
(60) Provisional application No. 62/993,822, filed on Mar. 24, 2020.

(51) Int. Cl. G06F 30/20; G07C 5/08

(52) U.S. Cl. CPC G06F 30/20; G07C 5/0808

(57) ABSTRACT

The present disclosure is directed to autonomous vehicle service assignment simulations using simulated remote operators. In particular, a computing system comprising one or more computing devices can obtain data associated with a simulated autonomous vehicle to use within a simulation environment based at least in part on a service assignment. The computing system can generate one or more simulated remote assistance operators. The computing system can initiate a simulation of a service assignment using the data associated with the simulated autonomous vehicle to perform the service assignment within the simulation environment. The computing system can provide one or more simulated events from the one or more simulated remote assistance operators to the simulated autonomous vehicle. The computing system can determine whether the simulated autonomous vehicle has successfully completed the service assignment based at least in part on the current state of the simulation.

### RELATED APPLICATION

This application claims priority to and the benefit of U.S. Provisional Patent Application No. 62/946,718, filed Dec. 11, 2019, and U.S. Provisional Patent Application No. 62/993,822, filed Mar. 24, 2020 which are hereby incorporated by reference in its entirety.

### FIELD

The present disclosure relates generally to autonomous vehicles. More particularly, the present disclosure relates to using simulation systems to test autonomous vehicles.

### BACKGROUND

An autonomous vehicle is a vehicle that is capable of sensing its environment and navigating without human input. In particular, an autonomous vehicle can observe its surrounding environment using a variety of sensors and can attempt to comprehend the environment by performing various processing techniques on data collected by the sensors. Given knowledge of its surrounding environment, the autonomous vehicle can identify an appropriate motion path for navigating through such surrounding environment.

### SUMMARY

Aspects and advantages of embodiments of the present disclosure will be set forth in part in the following description, or can be learned from the description, or can be learned through practice of the embodiments.

The method can include obtaining data associated with a simulated autonomous vehicle to use within a simulation environment based at least in part on a service assignment. The method can include generating one or more simulated remote assistance operators. The method can include initiating a simulation of a service assignment using the data associated with the simulated autonomous vehicle to perform the service assignment within the simulation environment, wherein upon initiation an initial state of the service assignment is assigned to be a current state of the simulation. The method can include providing one or more simulated events from the one or more simulated remote assistance operators to the simulated autonomous vehicle, the one or more simulated events being associated with the service assignment and causing the current state of the simulation to transition from a first state of the service assignment to a second state of the service assignment. The method can include determining whether the simulated autonomous vehicle has successfully completed the service assignment based at least in part on the current state of the simulation.

Other aspects of the present disclosure are directed to various systems, apparatuses, non-transitory computer-readable media, user interfaces, and electronic devices.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which refers to the appended figures, in which:

FIG. 1 depicts an example system for controlling the navigation of a vehicle according to example embodiments of the present disclosure;

FIG. 2 depicts an example entity infrastructure according to example embodiments of the present disclosure;

FIG. 3 depicts an example vehicle service test system infrastructure according to example embodiments of the present disclosure;

FIG. 4 depicts an example entity infrastructure according to example embodiments of the present disclosure;

FIG. 5 depicts a state machine diagram according to example embodiments of the present disclosure;

FIG. 6 depicts an example data flow diagram according to example embodiments of the present disclosure;

FIG. 7 depicts a flow diagram of an example method for enabling simulated remote operators in a simulation according to example embodiments of the present disclosure;

FIG. 8 depicts an example system with units for performing operations and functions according to example aspects of the present disclosure; and

FIG. 9 depicts example system components according to example aspects of the present disclosure.

### DETAILED DESCRIPTION

Generally, the present disclosure is directed to improved techniques for simulating the end-to-end distribution and performance of a service assignment by an autonomous vehicle via a service entity infrastructure. For example, a third-party entity may want to test whether the autonomous vehicles in the third-party entity's fleet of autonomous vehicles correctly perform a specific service assignment (e.g., pick-up a passenger from a first location and drop the passenger off at a second location). To test this specific task, a user associated with the third-party entity can request that the simulation system create a simulation (e.g., using an application at a computing device associated with the third-party/user). The user can request the simulation of an autonomous vehicle associated with the third-party entity and a simulated environment in which to run the simulation. One important aspect of the performance of a specific task can be the interaction with one or more remote assistance operators. A remote assistance operator can include any operator who assists an autonomous vehicle from a remote position (with respect to the vehicle), including but not limited to human operators and computer-based, virtual operators. The remote assistance operators can assist in resolving any problems or tasks that the autonomous vehicle is unable to resolve independently. Thus, the simulation system can generate one or more simulated remote assistance operators to allow testing of the interactions between the simulated autonomous vehicle and the simulated remote assistance operators. The simulation system can use the simulated remote assistance operators to generate one or more events (e.g., simulating actions taken by one or more remote assistance operators) that are required for a simulated service assignment. The simulation system can monitor whether the simulated autonomous vehicle responds correctly to the generated events and that the simulated system correctly completes the simulated service assignment.

The systems and methods of the present disclosure provide improved techniques to simulate an autonomous vehicle interacting with a service entity infrastructure. More particularly, a simulation system generates a simulation that includes a simulated autonomous vehicle, a simulated environment, and one or more simulated remote assistance operators. A third-party entity may want to test whether the autonomous vehicles in the third-party entity's fleet of autonomous vehicles correctly perform one or more of a variety of service assignments (e.g., pick-up a passenger from a first location and drop the passenger off at a second location). One or more of these service assignments may include interaction with a remote assistance operator. To ensure that the simulated autonomous vehicle (and by extension, the actual autonomous vehicle associated with the simulated autonomous vehicle) is configured to correctly interact with remote assistance operators, the simulation system can simulate service assignments that include interaction with one or more remote assistance operators as part of the process of completing the service assignment. For example, if the service assignment is to transport a user from a first location to a second location in response to the user's request, one or more remote assistance operators may be employed to ensure that the cabin of the autonomous vehicle meets one or more cleanliness criteria (e.g., a cabin check) and that the user has successfully entered and/or exited the autonomous vehicle.

To test interactions with a remote assistance operator, a user (e.g., either associated with the service entity or associated with a third-party entity) can request that the simulation system create a simulation (e.g., using an application at a computing device associated with the user) including a simulation of an autonomous vehicle, a simulation of one or more remote assistance operators, and a simulated environment in which to run the simulation. The user can also select a specific service assignment to be simulated. Thus, the user can select a service assignment that includes interaction with a remote assistance operator for at least one state in the multi-state process associated with the service assignment. The simulation system can then initiate the simulation as requested and populate it with a simulated autonomous vehicle and one or more simulated remote assistance operators. The simulated system can simulate the performance of the specific service assignment selected by the user.

Once the simulation has been initiated, the simulation system can access information about the service assignment and generate one or more events to simulate the selected service assignment. Specifically, the information about the service assignment can include information describing a series of states that represent particular steps that need to be performed to complete the service assignment. Each state can be associated with one or more expected events that can move the simulation from a first state to a second state. In some examples, the associated events may be generated by the simulated autonomous vehicle. The simulation system can monitor whether the autonomous vehicle generates the correct events at the expected times to move the simulation to the next state in the process and use that information to evaluate whether the simulated autonomous vehicle is correctly performing the simulated service assignment.

At each state in the multi-state process associated with a service assignment, the simulation system can determine what, if any, events are expected at that state. Some states can be associated with events expected to be received from the autonomous vehicle. In this case, the simulation system can determine whether the expected event is received from the simulated autonomous vehicle. In another example, an event can be expected to be generated by a remote assistance operator. In this case, the simulation system can cause one or more of the simulated remote assistance operators to generate one or more expected events. In some examples, user input can be used to generate the expected events. For example, if the current state in a service assignment is a cabin check, the expected event is one of either an approval event (e.g., the cabin check has passed the evaluation by the remote assistance operator) or a denial event (e.g., the cabin check has failed the evaluation by the remote assistance operator). A user controlling and/or monitoring the simulation can select which of the two events to generate. In some examples, the simulation service can automatically generate events without user input.

By executing specific service assignments to test the autonomous vehicle's interactions with remote assistance operators, the simulation system can allow potential problems to be identified before the service entity or third-party autonomous vehicles are used in live testing and/or for actual service performance. Ultimately, the technology described herein can allow autonomous vehicles to be tested in a safe, isolated, and consistent testing environment.

Although the following overview describes the use of simulated autonomous vehicles in various example embodiments, the systems and methods of the present disclosure can also be utilized with real-world autonomous vehicles deployed within a geographic area. Moreover, while several examples are described with respect to third party entities and third-party autonomous vehicles, such implementations can also be utilized by a service entity and the autonomous vehicles associated with the service entity.

More particularly, a service entity (e.g., service provider, owner, manager, or platform) can use one or more vehicles (e.g., ground-based vehicles such as automobiles, trucks, bicycles, scooters, other light electric vehicles, etc.; flight vehicles; and/or the like) to provide a vehicle service such as a transportation service (e.g., a rideshare service), a courier service, a delivery service, and so on. For example, the service entity (e.g., via its operations computing system) can receive requests for vehicle services (e.g., from a user) and generate service assignments (e.g., indicative of the vehicle service type, origin location, destination location, and/or other parameters) for the vehicle(s) to perform. The vehicle(s) can be autonomous vehicles that include various systems and devices configured to control the operation of the vehicle. For example, an autonomous vehicle can include an onboard vehicle computing system for operating the autonomous vehicle (e.g., located on or within the autonomous vehicle). The vehicle computing system can obtain sensor data from sensor(s) onboard the vehicle (e.g., cameras, LIDAR, RADAR), attempt to comprehend the vehicle's surrounding environment by performing various processing techniques on the sensor data, and generate an appropriate motion plan through the vehicle's surrounding environment. Moreover, an autonomous vehicle can be configured to communicate with one or more computing devices that are remote from the vehicle. For example, the autonomous vehicle can communicate with a remote computing system that can be associated with the service entity, such as the service entity's operations computing system. The operations computing system can include a plurality of system clients that can help the service entity monitor, communicate with, manage, etc. autonomous vehicles. In this way, the service entity can manage the autonomous vehicles to provide the vehicle services of the entity.

The autonomous vehicles utilized by the service entity to provide the vehicle service can be associated with a fleet of that service entity or a third-party. For example, the service entity may own, lease, etc. a fleet of autonomous vehicles that can be managed by the service entity (e.g., via system clients) to provide one or more vehicle services (“service entity autonomous vehicles” or “first party autonomous vehicles”). In some implementations, an autonomous vehicle can be associated with a third-party entity such as, for example, an individual, an original equipment manufacturer (OEM), or another entity (e.g., a “third-party autonomous vehicle”). Even though such an autonomous vehicle may not be included in the fleet of autonomous vehicles of the service entity, the platforms of the present disclosure can allow such a third-party autonomous vehicle to still be utilized to provide the vehicle services offered by the service entity, access the service entity system clients, etc.

The service entity's infrastructure can include an offboard trip testing (OTT) system that can help verify that autonomous vehicles (e.g., third-party autonomous vehicles, etc.) are able to fully utilize the backend services (e.g., system clients) of the infrastructure as well as to complete service assignments of the service entity. The OTT system can be configured to simulate the end-to-end distribution, performance, and completion of a service assignment by an autonomous vehicle via the entity's infrastructure. For example, the OTT system can create a simulated service assignment (e.g., to transport a simulated user), assign the simulated service assignment to a simulated autonomous vehicle (e.g., representative of the third-party autonomous vehicle), and monitor the performance of the simulated autonomous vehicle. The simulated autonomous vehicle can be provided access to the backend services of the entity's infrastructure while completing the service assignment within the simulated environment. Moreover, the OTT system can provide a graphical user interface that allows a human user to study the performance of the simulated autonomous vehicle. The OTT system can include various subsystems that allow the OTT system to run test simulations and present the results of the simulation. These operations can also be utilized with a real-world autonomous vehicle.

The OTT system can include a remote assistance operator simulation subsystem to manage generation and simulation of one or more simulated remote assistance operators. The remote assistance operator simulation subsystem may be configured to generate one or more remote assistance operators and monitor the performance of the generated simulated remote assistance operators. The OTT system (also referred to as a simulation system) can use remote assistance operators to test both the interaction of simulated autonomous vehicles with remote assistance operators during execution of one or more simulated service assignments and to test the operation of the service entity itself as it assigns remote assistance operators to a variety of tasks.

As noted above, a significant use of the remote assistance operator simulation subsystem can be to test the ability of simulated autonomous vehicles to correctly interact with the remote assistance operators. To do so, the simulation system can generate a simulation environment and provide a simulated autonomous vehicle with a service assignment that includes interaction with a remote assistance operator. The service entity can provide a plurality of different service assignments that can be simulated by the simulation system. For example, the service entity can provide vehicle services such as a transportation service (e.g., rideshare service), a courier service, and a delivery service. As noted above, the simulation system can access data describing one or more states that the simulation passes through when performing each service assignment in the plurality of different service assignments.

The simulation system can include data representing a specific service assignment. In some examples, the data representing a specific service assignment can be represented as a directed state graph. A directed state graph includes a plurality of nodes and edges between those nodes. Each edge has a given direction, such that the graph moves from one node, across an edge, to another node, but cannot return. In this example, each node in a directed state graph associated with a specific service assignment can represent a state (or step) in that specific service assignment. For example, a directed state graph for “giving a passenger a ride to a destination” can include a series of possible states including, but not limited to: waiting for a ride request, traveling to a designated pickup zone, waiting for a passenger to enter the autonomous vehicle, traveling to a designated destination zone, and waiting for the passenger to exit the autonomous vehicle. Each node (e.g., a state in the specific service assignment can be connected to one or more other nodes by edges. Each of the edges represents a set of preconditions that must be met to move from the first node to the second node. In some examples, a precondition can include one or more events that are expected to occur.

A rider transport service assignment can be associated with data describing a plurality of states, each state representing a particular step in a process that must be executed to successfully deliver a rider to a specified destination including, but not limited to: the autonomous vehicle coming online and signaling readiness, receiving a positive cabin check from a remote assistance operator, receiving a transportation request from a user, navigating to a user's pick-up point, picking up that user, navigating to the user's designated destination, dropping off the user within an expected amount of time, and receiving confirmation from a remote assistance operator confirming the user has been successfully dropped off and the autonomous vehicle is prepared to accept another service assignment. In some examples, each step in the process of a simulated service assignment may be represented by a state of the simulation. Each service assignment can also include one or more expected events associated with each state of the service assignment. In the above example, after a remote assistance operator (in this case a simulated remote assistance operator) generates an event indicating that the simulated autonomous vehicle has passed the cabin check and a service assignment (e.g., a job/trip/task offer) event has been generated, the service assignment data can indicate that the simulated autonomous vehicle is expected to accept the job/trip/task offer. In some examples, if an expected event fails to occur, the simulation system can transition the simulation into a failure state and end the simulation.

While the simulation of the service assignment is being performed, the remote assistance operator simulation subsystem can determine, at each state, whether the state includes an event associated with and/or generated by a remote assistance operator. When testing a remote assistance operator, the simulation system (or a user interacting with the simulation system) can select service assignments that include at least one event that is expected to be received from a remote assistance operator. When the remote assistance operator simulation subsystem determines that the current state has an expected event associated with the remote assistance operator, the remote assistance operator simulation subsystem can assign a simulated remote assistance operator to provide the expected event. In some examples, the simulation service can leverage the existing backend tools of the service entity to assign a simulated remote assistance operator to generate the expected event from a plurality of possible simulated remote assistance operators. In some examples, the remote assistance operator simulation subsystem can employ a very simple assignment system (e.g., using a FIFO queue for simulated remote assistance operators). In other examples, the back-end tools of the service entity can assign a simulated remote assistance operator based on one or more operator parameters, including operator location, operator history, operator training, and/or one or more parameters associated with the autonomous vehicle, including, but not limited to the geographic location of the autonomous vehicle, the make of the autonomous vehicle, the fleet operator of the autonomous vehicle, and so on.

A service assignment may include multiple states that have expected events associated with remote assistance operators. In this case, the remote assistance operator simulation subsystem can assign a new simulated remote assistance operator each time a remote assistance operator is required. Alternatively, the simulation system can ensure that if a service assignment includes more than one event generated by a remote assistance operator, the same simulated remote assistance operator will be assigned to generate all the events associated with the particular service assignment. Doing so can have the advantage of efficiency because this mirrors the actual functioning of the live service entity in which the system can prioritize assigning the same/similar remote assistance operator whenever needed throughout all the states of a specific service assignment (e.g., an autonomous vehicle performing one ride request). This can allow the remote assistance operator to be familiar with the specific service assignment and thus be more efficient in responding. Similarly, the system may prioritize assigning the same remote assistance operator to a specific autonomous vehicle over a plurality of service assignments. The simulation system can allow for testing of any method of assigning remote assistance operators to ensure that the simulated autonomous vehicle will operate correctly in all cases.

As an example, a user can request a simulation of a rider request service on a simulated autonomous vehicle from the simulation system. In response, the simulation system can initiate a simulation, including a simulated autonomous vehicle, a simulated environment, and one or more simulated remote assistance operators. In some examples, the first state in the multi-state process of initiating a rider request service assignment is receiving a notification from the semi-autonomous vehicle that it has come online, and it is prepared to accept rider requests. In some examples, the simulation system can monitor events received from the simulated autonomous vehicle. If the expected event is not received, the simulation may enter the failure state. Once the simulated autonomous vehicle has generated a “ready to receive ride requests” event, the simulation system can move to the next state in the process associated with this particular service assignment. For example, the next state may be a cabin check performed by a remote assistance operator.

In some examples, the simulated remote assistance operator can generate a simulated event to represent the outcome of a simulated cabin check. The simulation system can cause the remote assistance operator to generate either a “cabin check passed” event or a “cabin check failed” event. The simulation system can monitor the reaction of the simulated autonomous vehicle to the received event. The simulation system can expect different reactions from the simulated autonomous vehicle depending on whether the simulated remote assistance operator generates a “cabin check passed” event or a “cabin check failed” event.

If the simulated remote assistance operator generates a “cabin check passed” event, the simulated autonomous vehicle can move to the next state in the simulated service assignment. For example, the next state in the simulated service assignment can include sending a notification to the service entity, the notification indicating that the simulated autonomous vehicle is ready to accept service assignments. The simulation system can monitor for notifications from the simulated autonomous vehicle and, based on whether a notification is received, determine whether the vehicle is correctly responding to the “cabin check passed” event.

If the simulated remote assistance operator generates a “cabin check failed” event, the simulation system can monitor the simulation to ensure that the simulated autonomous vehicle is correctly responding to the “cabin check failed” event. For example, if the simulated remote operator generates a “cabin check failed” event, the simulated system can expect the simulated autonomous vehicle to respond such that the issue that caused the “cabin check failed” event can be addressed. In some examples, the “cabin check failed” event can include data indicating the issue that resulted in the “cabin check failed” event. For example, the cabin of the autonomous vehicle may be unclean. In response, the simulated autonomous vehicle can travel to a predetermined cleaning vendor location. Thus, the simulation system can monitor the simulated autonomous vehicle's response to determine whether the autonomous vehicle is correctly responding to each generated event.

In some examples, if the autonomous vehicle generates a notification indicating that the simulated autonomous vehicle is ready to accept service assignments, the simulation system can generate an event that simulates a “rider request” event. It should be noted that the simulation system can use a simulated actor (e.g., a simulation of a user) to generate the “rider request” event. The “rider request” event can include data describing a pick-up location and a drop-off location.

After causing a “rider request” event to be generated, the simulation system can monitor whether the simulated autonomous vehicle moves to the pickup location within the simulated environment. Once the simulated autonomous vehicle has moved to the pickup location within the simulated environment, the simulation system can determine whether the vehicle has generated a “rider successfully picked up” event within an expected time. In some implementations, the “rider pickup” event can also be confirmed by a simulated remote assistance operator. Once the simulated autonomous vehicle has successfully picked up a rider, the simulation service can transition from the current state to the next state in the process, which in this example can be traveling to the drop-off location. At each state, the simulation system can monitor the simulation to ensure that the simulated autonomous vehicle transmits events that are expected at each state in the process.

Once the simulated autonomous vehicle has reached the drop-off destination, the simulated vehicle can simulate dropping off the rider. In some examples, a simulated remote assistance operator can then be tasked with generating an event representing whether the rider has successfully exited the vehicle. In some examples, the simulated remote assistance operator can also simulate performing a vehicle readiness check (which may include a cabin check) and generating an event representing the results of the vehicle readiness check. The simulated autonomous vehicle can use the vehicle readiness check event to determine whether to prepare itself for another rider request or to perform another action (e.g., proceed to a service station for maintenance or cleaning).

In some examples, an unexpected event can occur (e.g., the simulated autonomous vehicle fails to move to the next state in response to receiving an event from the simulated remote operator). In response, the simulation system can enter a failure state. In some examples, any unexpected event can serve as the precondition to enter into one or more failure states. A failure state can also be a terminal state, meaning that the simulation of the service assignment ends when that state is reached. For example, a simulated remote assistance operator can generate a cabin check for a particular state of a service assignment process. The cabin check event can be transmitted to the simulated autonomous vehicle. In some examples, if the simulated autonomous vehicle is correctly functioning, it can, in response to the received event, enter a new state in the service assignment process and generate an event in response. If the expected event is not received from the simulated autonomous vehicle within a predetermined period, the simulation system can determine that the simulated autonomous vehicle has failed to respond as expected to the event generated by the simulated remote assistance operator. The simulation system can then cause the simulation to enter a failure state. In some examples, a failure state may not be terminal. For example, if the simulated autonomous vehicle initially fails to reach the pick-up zone, the simulation system can cause the simulation to enter a failure state that has directions such as “contact a remote operator for assistance” which allows for additional progress in the simulated service assignment.

The simulation system can continue to receive events and transition the simulation to new states until a terminal state is reached. When a service assignment is successfully completed, the final state can be a successful termination state. In some examples, each service assignment can be associated with metadata that determines whether each state (e.g., each node in the state graph) is terminal. Once a terminal state is reached, the simulation system can analyze collected information to identify any potential problems with the performance of the simulated autonomous vehicle during the simulation (e.g., failure to produce expected events at the appropriate times).

For example, using an electronic device, a user can transmit a request to start a simulation to a communication interface associated with the simulation system. In some examples, the communication interface can be a vendor integration platform that provides access through API calls to the backend services of the service entity. When configuring a simulation, a third-party entity (e.g., a computing system associated therewith) can request generation of a simulation environment, configure it with a set of actors (e.g., simulated user(s), simulated autonomous vehicle(s), simulated driver, simulated remote assistance operators, etc.), run simulations, and deactivate the simulation environment after the simulation run is completed. In some implementations, an actor can be used only in one simulation environment at any given time to provide isolation between simulation runs. Simulation environments (e.g., sandboxes, etc.) can be used for capturing test logs, actor state changes (e.g., which can be replayed or reproduced), and/or other information. A simulation environment service can use an external database for persisting data (e.g., sandbox data, etc.) and an actor registry. Such data can include, for example, static entries such as a registry of actors and their keys in other systems and information about which actors belong within which sandbox.

In addition to using the simulated remote assistance operators to test autonomous vehicles, the simulation system can use the simulated remote assistance operators to test the functionality of the remote assistance operators themselves. For example, as noted above, when a state in a service assignment includes one or more actions or events to be taken by the remote assistance operator, the service entity can assign a remote assistance operator from a plurality of remote assistance operators to perform the action (or generate the event). The simulation system can test whether the assignment of remote assistance operators is working as intended.

To effectively test the assignment of remote assistance operators, the simulation system can generate a plurality of simulated remote assistance operators. In some examples, each remote assistance operator can be assigned one or more operator characteristics and/or an operator history. With one or more operator characteristics, the simulation system (or the remote assistance operator simulation subsystem) can use the existing backend systems for the service entity to determine which simulated remote assistance operator to assign to generate an expected event. For example, the service entity may assign remote assistance operators to service assignments with specific autonomous vehicles based on one or more factors including the similarity of the current service assignment with assignments the remote assistance operators have been associated with in the past, the location of the remote assistance operator, the expertise or experience of the remote assistance operator, and so on. By assigning characteristics to simulated remote assistance operators, the simulation system can evaluate how a simulated autonomous vehicle responds to events generated by the same simulated remote assistance operator or events generated by different simulated remote assistance operators during a single service assignment.

In addition, each simulated remote assistance operator can include metadata that describes the specific simulation (or simulated environment) that it is associated with. In this way, the simulation system can make use of the backend tools of the live system without the possibility of a simulated remote assistance operator being assigned to a live autonomous vehicle and without the possibility of a real remote assistance operator being assigned to a simulated autonomous vehicle. For example, each simulated autonomous vehicle, remote assistance operator, and actor can be assigned to a specific environment. The service entity's backend system can then be configured to ensure that when a request is received (e.g., for a service or a remote assistance operator), each request is assigned to the correct environment (e.g., the live system, simulation 1, simulation 2, and so on).

In addition, the simulation system can enable testing of various aspects of the remote assistance operator assignment system. For example, the simulation system can test whether the remote assistance operator assignment system efficiently assigns remote assistance operators to particular service assignments. For example, the simulation system can run simulations with a plurality of remote assistance operators to evaluate whether the remote assistance operator assignment system will assign the same remote assistance operator to a specific service assignment that requires two interactions with a remote assistance operator within a single assignment.

The simulation system can also evaluate, using testing, specific service assignment processes and flows associated with remote assistance operators. For example, during a ride request assignment, a simulated remote assistance operator can be tasked with performing a vehicle or cabin check on the simulated autonomous vehicle after arriving at the destination location to ensure the simulated autonomous vehicle is ready to receive another ride request. To improve this process, the simulation system can test to determine when is the optimal time to begin the simulated remote assistance operator session. In some examples, the simulated remote assistance operator session may not begin until the simulated autonomous vehicle has reached a destination. In another example, the simulation system may begin the process of assigning a simulated remote assistance operator and initiating a simulated session once the simulated autonomous vehicle has come within a predetermined range of its destination within the simulation. In another example, the simulation system may track the current estimated time of arrival for the simulated autonomous vehicle and only begin the simulated remote assistance operator session once the estimated time of arrival has fallen below a predetermined threshold. The simulation system can simulate each of the scenarios and generate data that can be used to determine which results in a better experience for passengers and allows an autonomous vehicle to effectively move between service assignments.

In addition, the simulation system can, using simulations, test the remote assistance assignment system to identify conditions in which the assignment of remote assistance operators fails. For example, the simulation system can generate a simulation in which no open remote assistance operator can be found or where the connection with a remote assistance operator is lost. The simulation system can capture data reflecting the responses of the simulated autonomous vehicle and backend system and provide that data for additional analysis. By testing these scenarios in a simulated environment, the simulation system can prevent the cost and inconvenience that may result if these situations were to occur during the live operation of the service entity.

The systems and methods described herein provide a number of technical effects and benefits. Specifically, the systems and methods of the present disclosure provide improved techniques for evaluating the ability of an autonomous vehicle (e.g., of a third-party vehicle fleet) to integrate and communicate with the infrastructure of a service entity while performing complicated tasks that involve interactions with remote assistance operators. For instance, the scenario simulation system (and its associated processes) allow the service entity and/or a third-party entity (e.g., vehicle vendor) to create test actors such as simulated autonomous vehicles and simulated remote assistance operators. The simulation system can enable the selection of multi-state service assignments then match them with a simulated autonomous vehicle. The simulation system provides a third-party entity with an event generation system that simulates the actions of users (e.g., riders) and remote assistance operators and verifies that the autonomous vehicles progress through to completion of a selected service assignment. Moreover, the simulation system allows for this type of simulation to occur in a simulation environment (e.g., sandbox, etc.) that is isolated from real-world service assignment production, allocation, and coordination. This leads to improved integration with the service entity's infrastructure (and the public API platform) by making the integration process more straightforward and helping to build more confidence in the platform, without having to distribute a real-world production service assignment to the autonomous vehicle. As such, integration issues can be efficiently identified in an offline, isolated environment before deployment of the vehicles in the real-world.

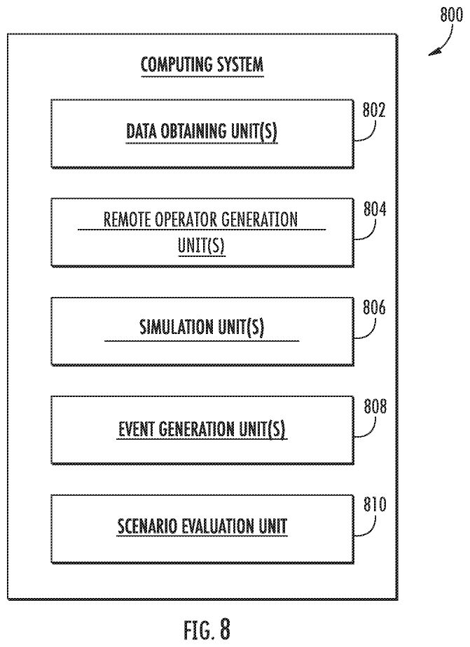

Various means can be configured to perform the methods and processes described herein. For example, FIG. 8 depicts a diagram of an example computing system that can include data obtaining unit(s) 802, remote operator generation unit(s) 804, simulation unit(s) 806, event generation unit(s) 808, and/or other means for performing the operations and functions described herein. In some implementations, one or more of the units may be implemented separately. In some implementations, one or more units may be a part of or included in one or more other units. These means can include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The means can also, or alternately, include software control means implemented with a processor or logic circuitry for example. The means can include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware.

The means can be programmed to perform one or more algorithm(s) for carrying out the operations and functions described herein. For instance, the means can be configured to obtain data associated with a simulated autonomous vehicle to use within a simulation environment based at least in part on a service assignment. The means can be configured to obtain generate one or more simulated remote assistance operators for the simulation. For example, the means can be configured to generate a simulated user, a simulated autonomous vehicle, and one or more remote assistance operators within the simulation environment. The means can be configured to generate a simulated autonomous vehicle within a simulation environment based at least in part on the data describing the autonomous vehicle. The means can be configured to initiate a simulation of a service assignment using the simulated autonomous vehicle to perform the service assignment within the simulation environment. The means can be configured to transmit one or more simulated events from the simulated remote assistance operators to the simulated autonomous vehicle, the simulated events enabling the autonomous vehicle to attempt to complete the service assignment. The means can be configured to determine, based on one or more criteria whether the autonomous vehicle has successfully completed the service assignment.

With reference to the figures, example embodiments of the present disclosure will be discussed in further detail.

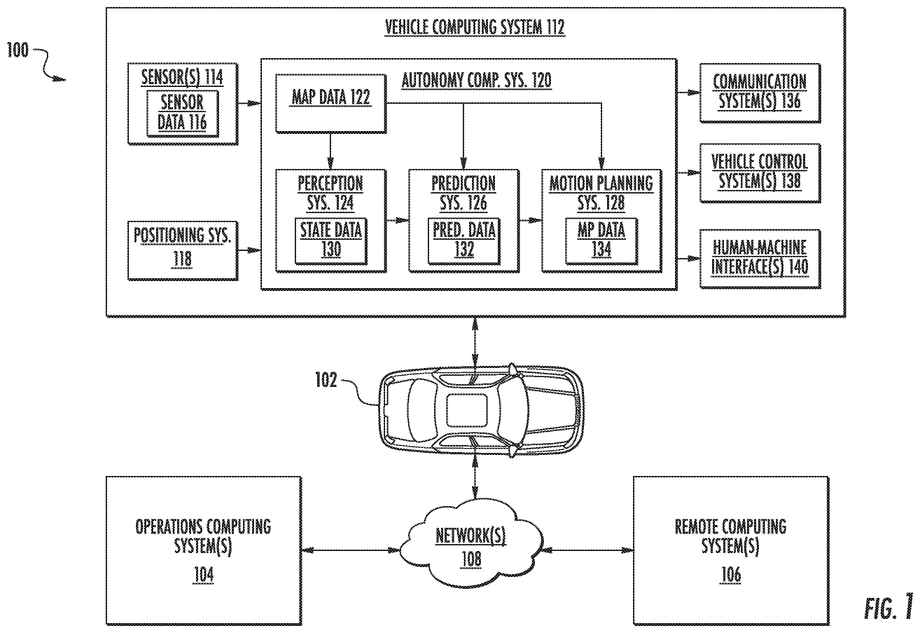

FIG. 1 depicts a block diagram of an example system 100 for controlling the navigation of a vehicle according to example embodiments of the present disclosure. As illustrated, FIG. 1 shows a system 100 that can include a vehicle 102; an operations computing system 104; one or more remote computing devices 106; a communication network 108; a vehicle computing system 112; one or more autonomy system sensors 114; autonomy system sensor data 116; a positioning system 118; an autonomy computing system 120; map data 122; a perception system 124; a prediction system 126; a motion planning system 128; state data 130; prediction data 132; motion plan data 134; a communication system 136; a vehicle control system 138; and a human-machine interface 140.

The operations computing system 104 can be associated with a service provider (e.g., service entity) that can provide one or more vehicle services to a plurality of users via a fleet of vehicles (e.g., service entity vehicles, third-party vehicles, etc.) that includes, for example, the vehicle 102. The vehicle services can include transportation services (e.g., rideshare services), courier services, delivery services, and/or other types of services.

The operations computing system 104 can include multiple components for performing various operations and functions. For example, the operations computing system 104 can include and/or otherwise be associated with the one or more computing devices that are remote from the vehicle 102. The one or more computing devices of the operations computing system 104 can include one or more processors and one or more memory devices. The one or more memory devices of the operations computing system 104 can store instructions that when executed by the one or more processors cause the one or more processors to perform operations and functions associated with operation of one or more vehicles (e.g., a fleet of vehicles), with the provision of vehicle services, and/or other operations as discussed herein.

For example, the operations computing system 104 can be configured to monitor and communicate with the vehicle 102 and/or its users to coordinate a vehicle service provided by the vehicle 102. To do so, the operations computing system 104 can manage a database that includes data including vehicle status data associated with the status of vehicles including the vehicle 102. The vehicle status data can include a state of a vehicle, a location of a vehicle (e.g., a latitude and longitude of a vehicle), the availability of a vehicle (e.g., whether a vehicle is available to pick-up or drop-off passengers and/or cargo, etc.), and/or the state of objects internal and/or external to a vehicle (e.g., the physical dimensions and/or appearance of objects internal/external to the vehicle).

The operations computing system 104 can communicate with the one or more remote computing devices 106 and/or the vehicle 102 via one or more communications networks including the communications network 108. The communications network 108 can exchange (send or receive) signals (e.g., electronic signals) or data (e.g., data from a computing device) and include any combination of various wired (e.g., twisted pair cable) and/or wireless communication mechanisms (e.g., cellular, wireless, satellite, microwave, and radio frequency) and/or any desired network topology (or topologies). For example, the communications network 108 can include a local area network (e.g. intranet), wide area network (e.g. Internet), wireless LAN network (e.g., via Wi-Fi), cellular network, a SATCOM network, VHF network, a HF network, a WiMAX based network, and/or any other suitable communications network (or combination thereof) for transmitting data to and/or from the vehicle 102.

Each of the one or more remote computing devices 106 can include one or more processors and one or more memory devices. The one or more memory devices can be used to store instructions that when executed by the one or more processors of the one or more remote computing devices 106 cause the one or more processors to perform operations and/or functions including operations and/or functions associated with the vehicle 102 including exchanging (e.g., sending and/or receiving) data or signals with the vehicle 102, monitoring the state of the vehicle 102, and/or controlling the vehicle 102. The one or more remote computing devices 106 can communicate (e.g., exchange data and/or signals) with one or more devices including the operations computing system 104 and the vehicle 102 via the communications network 108.

The one or more remote computing devices 106 can include one or more computing devices (e.g., a desktop computing device, a laptop computing device, a smart phone, and/or a tablet computing device) that can receive input or instructions from a user or exchange signals or data with an item or other computing device or computing system (e.g., the operations computing system 104). Further, the one or more remote computing devices 106 can be used to determine and/or modify one or more states of the vehicle 102 including a location (e.g., latitude and longitude), a velocity, acceleration, a trajectory, and/or a path of the vehicle 102 based in part on signals or data exchanged with the vehicle 102. In some implementations, the operations computing system 104 can include the one or more remote computing devices 106.

The vehicle 102 can be a ground-based vehicle (e.g., an automobile, bike, scooter, other light electric vehicle, etc.), an aircraft, and/or another type of vehicle. The vehicle 102 can be an autonomous vehicle that can perform various actions including driving, navigating, and/or operating, with minimal and/or no interaction from a human driver. The autonomous vehicle 102 can be configured to operate in one or more modes including, for example, a fully autonomous operational mode, a semi-autonomous operational mode, a park mode, and/or a sleep mode. A fully autonomous (e.g., self-driving) operational mode can be one in which the vehicle 102 can provide driving and navigational operation with minimal and/or no interaction from a human driver present in the vehicle. A semi-autonomous operational mode can be one in which the vehicle 102 can operate with some interaction from a human driver present in the vehicle. Park and/or sleep modes can be used between operational modes while the vehicle 102 performs various actions including waiting to provide a subsequent vehicle service, and/or recharging between operational modes.

An indication, record, and/or other data indicative of the state of the vehicle, the state of one or more passengers of the vehicle, and/or the state of an environment including one or more objects (e.g., the physical dimensions and/or appearance of the one or more objects) can be stored locally in one or more memory devices of the vehicle 102. Additionally, the vehicle 102 can provide data indicative of the state of the vehicle, the state of one or more passengers of the vehicle, and/or the state of an environment to the operations computing system 104, which can store an indication, record, and/or other data indicative of the state of the one or more objects within a predefined distance of the vehicle 102 in one or more memory devices associated with the operations computing system 104 (e.g., remote from the vehicle). Furthermore, the vehicle 102 can provide data indicative of the state of the one or more objects (e.g., physical dimensions and/or appearance of the one or more objects) within a predefined distance of the vehicle 102 to the operations computing system 104, which can store an indication, record, and/or other data indicative of the state of the one or more objects within a predefined distance of the vehicle 102 in one or more memory devices associated with the operations computing system 104 (e.g., remote from the vehicle).

The vehicle 102 can include and/or be associated with the vehicle computing system 112. The vehicle computing system 112 can include one or more computing devices located onboard the vehicle 102. For example, the one or more computing devices of the vehicle computing system 112 can be located on and/or within the vehicle 102. The one or more computing devices of the vehicle computing system 112 can include various components for performing various operations and functions. For instance, the one or more computing devices of the vehicle computing system 112 can include one or more processors and one or more tangible, non-transitory, computer readable media (e.g., memory devices). The one or more tangible, non-transitory, computer readable media can store instructions that when executed by the one or more processors cause the vehicle 102 (e.g., its computing system, one or more processors, and other devices in the vehicle 102) to perform operations and functions, including those described herein.

As depicted in FIG. 1, the vehicle computing system 112 can include the one or more autonomy system sensors 114; the positioning system 118; the autonomy computing system 120; the communication system 136; the vehicle control system 138; and the human-machine interface 140. One or more of these systems can be configured to communicate with one another via a communication channel. The communication channel can include one or more data buses (e.g., controller area network (CAN)), on-board diagnostics connector (e.g., OBD-II), and/or a combination of wired and/or wireless communication links. The onboard systems can exchange (e.g., send and/or receive) data, messages, and/or signals amongst one another via the communication channel.

The one or more autonomy system sensors 114 can be configured to generate and/or store data including the autonomy system sensor data 116 associated with one or more objects that are proximate to the vehicle 102 (e.g., within range or a field of view of one or more of the one or more sensors 114). The one or more autonomy system sensors 114 can include a Light Detection and Ranging (LIDAR) system, a Radio Detection and Ranging (RADAR) system, one or more cameras (e.g., visible spectrum cameras and/or infrared cameras), motion sensors, and/or other types of imaging capture devices and/or sensors. The autonomy system sensor data 116 can include image data, radar data, LIDAR data, and/or other data acquired by the one or more autonomy system sensors 114. The one or more objects can include, for example, pedestrians, vehicles, bicycles, and/or other objects. The one or more sensors can be located on various parts of the vehicle 102 including a front side, rear side, left side, right side, top, or bottom of the vehicle 102. The autonomy system sensor data 116 can be indicative of locations associated with the one or more objects within the surrounding environment of the vehicle 102 at one or more times. For example, autonomy system sensor data 116 can be indicative of one or more LIDAR point clouds associated with the one or more objects within the surrounding environment. The one or more autonomy system sensors 114 can provide the autonomy system sensor data 116 to the autonomy computing system 120.

In addition to the autonomy system sensor data 116, the autonomy computing system 120 can retrieve or otherwise obtain data including the map data 122. The map data 122 can provide detailed information about the surrounding environment of the vehicle 102. For example, the map data 122 can provide information regarding: the identity and location of different roadways, road segments, buildings, or other items or objects (e.g., lampposts, crosswalks and/or curb); the location and directions of traffic lanes (e.g., the location and direction of a parking lane, a turning lane, a bicycle lane, or other lanes within a particular roadway or other travel way and/or one or more boundary markings associated therewith); traffic control data (e.g., the location and instructions of signage, traffic lights, or other traffic control devices); and/or any other map data that provides information that assists the vehicle computing system 112 in processing, analyzing, and perceiving its surrounding environment and its relationship thereto.

The vehicle computing system 112 can include a positioning system 118. The positioning system 118 can determine a current position of the vehicle 102. The positioning system 118 can be any device or circuitry for analyzing the position of the vehicle 102. For example, the positioning system 118 can determine position by using one or more of inertial sensors, a satellite positioning system, based on IP/MAC address, by using triangulation and/or proximity to network access points or other network components (e.g., cellular towers and/or Wi-Fi access points) and/or other suitable techniques. The position of the vehicle 102 can be used by various systems of the vehicle computing system 112 and/or provided to one or more remote computing devices (e.g., the operations computing system 104 and/or the remote computing device 106). For example, the map data 122 can provide the vehicle 102 relative positions of the surrounding environment of the vehicle 102. The vehicle 102 can identify its position within the surrounding environment (e.g., across six axes) based at least in part on the data described herein. For example, the vehicle 102 can process the autonomy system sensor data 116 (e.g., LIDAR data, camera data) to match it to a map of the surrounding environment to get an understanding of the vehicle's position within that environment (e.g., transpose the vehicle's position within its surrounding environment).

The autonomy computing system 120 can include a perception system 124, a prediction system 126, a motion planning system 128, and/or other systems that cooperate to perceive the surrounding environment of the vehicle 102 and determine a motion plan for controlling the motion of the vehicle 102 accordingly. For example, the autonomy computing system 120 can receive the autonomy system sensor data 116 from the one or more autonomy system sensors 114, attempt to determine the state of the surrounding environment by performing various processing techniques on the autonomy system sensor data 116 (and/or other data), and generate an appropriate motion plan through the surrounding environment. The autonomy computing system 120 can control the one or more vehicle control systems 138 to operate the vehicle 102 according to the motion plan.

The perception system 124 can identify one or more objects that are proximate to the vehicle 102 based on autonomy system sensor data 116 received from the autonomy system sensors 114. In particular, in some implementations, the perception system 124 can determine, for each object, state data 130 that describes a current state of such object. As examples, the state data 130 for each object can describe an estimate of the object's: current location (also referred to as position); current speed; current heading (which may also be referred to together as velocity); current acceleration; current orientation; size/footprint (e.g., as represented by a bounding shape such as a bounding polygon or polyhedron); class of characterization (e.g., vehicle class versus pedestrian class versus bicycle class versus other class); yaw rate; and/or other state information. In some implementations, the perception system 124 can determine state data 130 for each object over a number of iterations. In particular, the perception system 124 can update the state data 130 for each object at each iteration. Thus, the perception system 124 can detect and track objects (e.g., vehicles, bicycles, pedestrians, etc.) that are proximate to the vehicle 102 over time, and thereby produce a presentation of the world around a vehicle 102 along with its state (e.g., a presentation of the objects of interest within a scene at the current time along with the states of the objects).

The prediction system 126 can receive the state data 130 from the perception system 124 and predict one or more future locations and/or moving paths for each object based on such state data. For example, the prediction system 126 can generate prediction data 132 associated with each of the respective one or more objects proximate to the vehicle 102. The prediction data 132 can be indicative of one or more predicted future locations of each respective object. The prediction data 132 can be indicative of a predicted path (e.g., predicted trajectory) of at least one object within the surrounding environment of the vehicle 102. For example, the predicted path (e.g., trajectory) can indicate a path along which the respective object is predicted to travel over time (and/or the velocity at which the object is predicted to travel along the predicted path). The prediction system 126 can provide the prediction data 132 associated with the one or more objects to the motion planning system 128.

The motion planning system 128 can determine a motion plan and generate motion plan data 134 for the vehicle 102 based at least in part on the prediction data 132 (and/or other data). The motion plan data 134 can include vehicle actions with respect to the objects proximate to the vehicle 102 as well as the predicted movements. For instance, the motion planning system 128 can implement an optimization algorithm that considers cost data associated with a vehicle action as well as other objective functions (e.g., cost functions based on speed limits, traffic lights, and/or other aspects of the environment), if any, to determine optimized variables that make up the motion plan data 134. By way of example, the motion planning system 128 can determine that the vehicle 102 can perform a certain action (e.g., pass an object) without increasing the potential risk to the vehicle 102 and/or violating any traffic laws (e.g., speed limits, lane boundaries, signage). The motion plan data 134 can include a planned trajectory, velocity, acceleration, and/or other actions of the vehicle 102.

As one example, in some implementations, the motion planning system 128 can determine a cost function for each of one or more candidate motion plans for the autonomous vehicle 102 based at least in part on the current locations and/or predicted future locations and/or moving paths of the objects. For example, the cost function can describe a cost (e.g., over time) of adhering to a particular candidate motion plan. For example, the cost described by a cost function can increase when the autonomous vehicle 102 approaches impact with another object and/or deviates from a preferred pathway (e.g., a predetermined travel route).

Thus, given information about the current locations and/or predicted future locations and/or moving paths of objects, the motion planning system 128 can determine a cost of adhering to a particular candidate pathway. The motion planning system 128 can select or determine a motion plan for the autonomous vehicle 102 based at least in part on the cost function(s). For example, the motion plan that minimizes the cost function can be selected or otherwise determined. The motion planning system 128 then can provide the selected motion plan to a vehicle controller that controls one or more vehicle controls (e.g., actuators or other devices that control gas flow, steering, braking, etc.) to execute the selected motion plan.

The motion planning system 128 can provide the motion plan data 134 with data indicative of the vehicle actions, a planned trajectory, and/or other operating parameters to the vehicle control systems 138 to implement the motion plan data 134 for the vehicle 102. For instance, the vehicle 102 can include a mobility controller configured to translate the motion plan data 134 into instructions. By way of example, the mobility controller can translate a determined motion plan data 134 into instructions for controlling the vehicle 102 including adjusting the steering of the vehicle 102 “X” degrees and/or applying a certain magnitude of braking force. The mobility controller can send one or more control signals to the responsible vehicle control component (e.g., braking control system, steering control system and/or acceleration control system) to execute the instructions and implement the motion plan data 134.

The vehicle computing system 112 can include a communications system 136 configured to allow the vehicle computing system 112 (and its one or more computing devices) to communicate with other computing devices. The vehicle computing system 112 can use the communications system 136 to communicate with the operations computing system 104 and/or one or more other remote computing devices (e.g., the one or more remote computing devices 106) over one or more networks (e.g., via one or more wireless signal connections, etc.). In some implementations, the communications system 136 can allow communication among one or more of the systems on-board the vehicle 102. The communications system 136 can also be configured to enable the autonomous vehicle to communicate with and/or provide and/or receive data and/or signals from a remote computing device 106 associated with a user and/or an item (e.g., an item to be picked-up for a courier service). The communications system 136 can utilize various communication technologies including, for example, radio frequency signaling and/or Bluetooth low energy protocol. The communications system 136 can include any suitable components for interfacing with one or more networks, including, for example, one or more: transmitters, receivers, ports, controllers, antennas, and/or other suitable components that can help facilitate communication. In some implementations, the communications system 136 can include a plurality of components (e.g., antennas, transmitters, and/or receivers) that allow it to implement and utilize multiple-input, multiple-output (MIMO) technology and communication techniques.

The vehicle computing system 112 can include the one or more human-machine interfaces 140. For example, the vehicle computing system 112 can include one or more display devices located on the vehicle computing system 112. A display device (e.g., screen of a tablet, laptop, and/or smartphone) can be viewable by a user of the vehicle 102 that is located in the front of the vehicle 102 (e.g., driver's seat, front passenger seat). Additionally, or alternatively, a display device can be viewable by a user of the vehicle 102 that is located in the rear of the vehicle 102 (e.g., a passenger seat in the back of the vehicle).

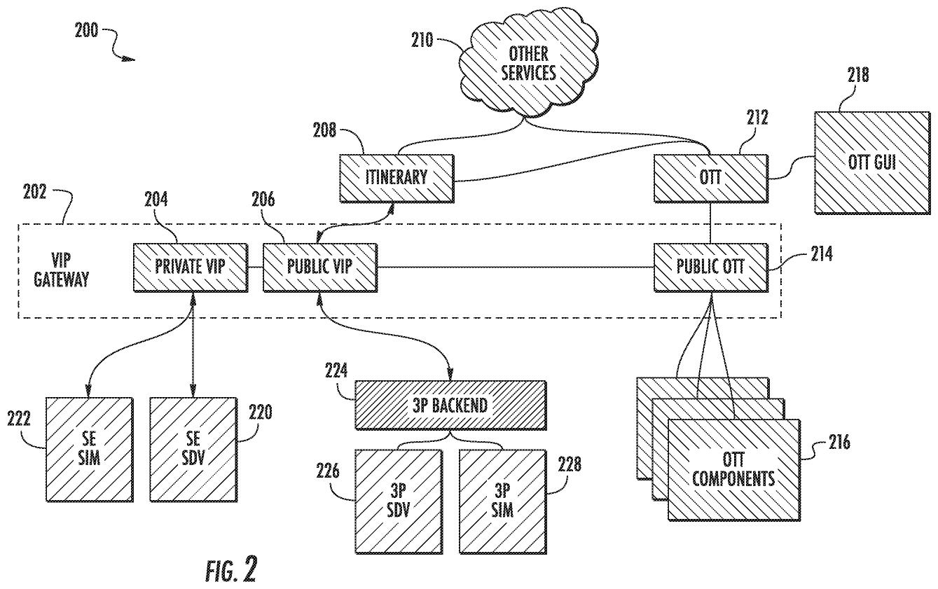

FIG. 2 depicts an example service entity infrastructure 200 according to example embodiments of the present disclosure. A service entity (e.g., service provider, owner, manager, platform, and so on) can use one or more vehicles (e.g., ground-based vehicles, flight vehicles, etc.) to provide one or more vehicle services such as a transportation service (e.g., rideshare service), a courier service, a delivery service, and/or the like. For example, the service entity (e.g., via its operations computing system) can receive requests for vehicle services (e.g., from a user) and generate service assignments (e.g., indicative of the vehicle service type, origin location, destination location, and/or other parameters) for the vehicle(s) to perform. The vehicle(s) can be autonomous vehicles that include various systems and devices configured to control the operation of the vehicle.

The autonomous vehicles utilized by the service entity to provide the vehicle service can be associated with a fleet of that service entity or a third-party. For example, the service entity may own, lease, etc. a fleet of autonomous vehicles that can be managed by the service entity (e.g., by system clients associated with a service entity system) to provide one or more vehicle services. In some implementations, an autonomous vehicle can be associated with a third-party entity such as, for example, an individual, an original equipment manufacturer (OEM), or another entity (e.g., a “third-party autonomous vehicle”). Even though such an autonomous vehicle may not be included in the fleet of autonomous vehicles of the service entity, the platforms of the present disclosure can allow such a third-party autonomous vehicle to still be utilized to provide the vehicles services offered by the service entity, access its system clients, etc.

The service entity can provide an infrastructure 200 that can allow the service entity to assign the service assignment to an autonomous vehicle of the service entity's fleet, an autonomous vehicle of another entity's fleet (e.g., “a third-party autonomous vehicle”), and/or the like. Such an infrastructure 200 can include a platform (e.g., vendor integration platform (VIP)) comprising one or more application programming interfaces (APIs) that are configured to allow third-party autonomous vehicles (e.g., third-party AV 226) and provider infrastructure endpoints (e.g., system clients that provide backend services, etc. such as itinerary service 208, other services 210, etc.) to communicate. For example, a service entity infrastructure 200 can include an application programming interface platform (e.g., public VIP 206) which can facilitate communication between third-party autonomous vehicles and endpoints to help aid the delivery of a service assignment to the autonomous vehicle, monitor vehicle progress, provide remote assistance, etc. and, ultimately to support the performance of a service assignment by the third-party autonomous vehicles. The application programming interface (API) platform can have one or more functional calls defined to be accessed by a third-party autonomous vehicle (e.g., third-party AV 226) or a managing entity of third-party autonomous vehicles (e.g., third-party backend 224). In some examples, the API platform is a public API platform, such as shown by public VIP 206. The service entity can also provide third-party simulated autonomous vehicle (e.g., third-party autonomous vehicle sim 228) access to one or more services of one or more backend systems of the service entity during a simulation through the API platform, for example, via a testing system API such as public OTT 214. The service entity can also provide a service entity simulated autonomous vehicle (e.g., entity autonomous vehicle sim 222) access to one or more services of one or more backend systems of the service entity during a simulation through the API platform.

The service entity infrastructure 200 can include a public API platform (e.g., public VIP 206) and a private API platform (e.g., private VIP 204) to facilitate services between the service entity infrastructure and autonomous vehicles (e.g., service entity autonomous vehicles 220, third-party autonomous vehicles 226). The public and/or private API platform can include one or more functional calls defined to be accessed by a third-party autonomous vehicle or a managing entity of third-part autonomous vehicles (and/or a service entity autonomous vehicle). For example, the public API platform (e.g., public VIP 206) can facilitate access to back-end services (e.g., provided by service entity backend system clients) by autonomous vehicles associated with one or more third-party vendors and/or the service entity's own fleet. The public VIP 206 can provide access to services such as service assignment services, routing services, supply positioning services, payment services, remote assist services, and/or the like. The private API platform (e.g., private VIP 204) can provide access (e.g., by service entity autonomous vehicles 220) to services that are specific to the service entity's autonomous vehicle fleet such as fleet management services, autonomy assistance services, and/or the like. Both the public VIP 206 and the private VIP 204 can include and/or be associated with a gateway API (e.g., VIP gateway 202) to facilitate communication from the autonomous vehicles to the service entity backend infrastructure services (e.g., backend system clients, etc.) and a vehicle API to facilitate communication from the service entity backend infrastructure services to the autonomous vehicles. Each of the platform's APIs can have separate responsibilities, monitoring, alerting, tracing, service level agreements (SLAs), and/or the like.

The service entity infrastructure 200 can include an OTT system 212 that can help verify that autonomous vehicles (e.g., entity autonomous vehicles, third-party autonomous vehicles, etc.) are able to fully utilize the backend services (e.g., system clients) of the service entity infrastructure 200 as well as to complete service assignments of the service entity. The OTT system 212 can be configured to simulate the end-to-end distribution, performance, and completion of a service assignment by an autonomous vehicle via the service entity infrastructure 200. For example, the OTT system 212 can create a simulated service assignment, assign the simulated service assignment to simulated autonomous vehicle (e.g., entity autonomous vehicle sim 222, third-party autonomous vehicle sim 228), and monitor the performance of the simulated autonomous vehicle. The simulated autonomous vehicle can be provided with access to the backend services of the service entity infrastructure 200 while completing the service assignment within a simulation environment. The service entity infrastructure 200 can include a testing system API, such as public OTT 214 to allow access to one or more services of one or more backend systems of the service entity via one or more OTT tools (e.g., OTT components 216) during a simulation through an API platform gateway (e.g., VIP gateway 202).

The OTT system 212 can include various sub-systems (e.g., OTT components 216, etc.) that allow the OTT system to run test simulations and present the results of the simulation. For instance, the OTT system can include a command line interface, a graphical user interface (e.g., OTT GUI 218), and an OTT library. The command line interface can be configured to manage test accounts (e.g., third party/vendor accounts, vehicle accounts, simulated user accounts, driver accounts, etc.). For example, the command line interface can be configured to create, delete, inspect, etc. data fields for test simulations/accounts to be utilized for simulation testing. The command line interface can also be configured to help facilitate the download of other tools, IDLs, libraries, etc. The OTT system 212 can also include a graphical user interface (e.g., OTT GUI 218) that allows a user to create simulated service assignments, visualize simulated service assignments, vehicles, and/or other information (e.g., logs, metrics, etc.), mock simulated user (e.g., rider, etc.) behavior, etc. The OTT system 212 can also include a library that allows for the programmatic performance of the functions of the command line interface and the graphical user interface. One or more of these sub-systems (e.g., OTT components 216) can be accessed outside of a network of the service entity, for example via public OTT 214.

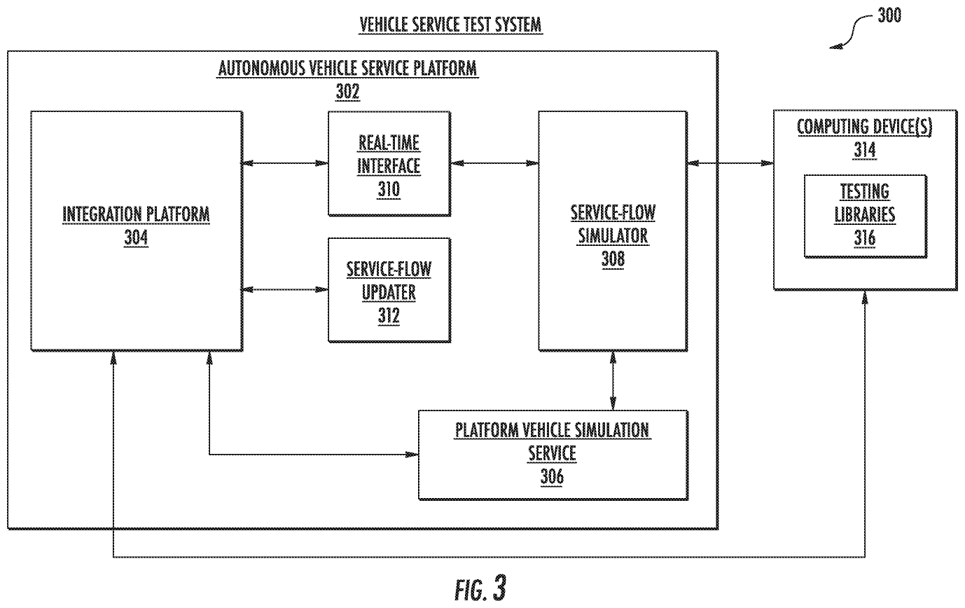

FIG. 3 depicts an example vehicle service test system 300 according to example embodiments of the present disclosure. A vehicle service test system, as illustrated in FIG. 3, can provide for evaluation of autonomous vehicle services through computer-implemented simulations of vehicle service-flows that utilize autonomous vehicles. A vehicle service test system 300 can include an autonomous vehicle service platform 302, an integration platform 304, a platform vehicle simulation service 306, a service-flow simulator 308, a real-time interface 310, a service-flow updater 312, one or more remote computing devices 314, one or more testing libraries 316, and/or the like.

A vehicle service test system 300 can provide one or more interfaces that enable users (e.g., software developers for autonomous vehicle computing systems, etc.) to design and test vehicle services using simulated autonomous vehicles. Data defining a simulated autonomous vehicle can be obtained in response to input received from a user through the one or more user interfaces. Similarly, data indicative of one or more parameters for at least one vehicle service simulation or scenario can be obtained, for example, in response to input received from a user through the one or more user interfaces. The test system may obtain from a remote computing system a request for an autonomous vehicle simulation. The test system can initiate one or more vehicle service simulations using the one or more parameters and the simulated autonomous vehicle. In this manner, users can define and debug vehicle service-flows within a single set of user interfaces. A user can manually control a vehicle service-flow in some examples by controlling an autonomous vehicle state. In other examples, a user can automate control of the vehicle service-flow using one or more predefined simulation scenarios. By providing a simulated testing environment that provides developer control over vehicle service-flows as well as autonomous vehicle definition, a quick and efficient technique for designing and evaluating vehicle service-flows can be provided.

The vehicle service test system 300 can be associated with an autonomous vehicle service platform 302. The autonomous vehicle service platform 302 can be associated with a service entity infrastructure which allows a service entity to provide vehicle services (e.g., transportation services (rideshare service), courier services, delivery services, etc.), for example, through vehicles in one or more vehicle fleets (e.g., service entity vehicle fleet, third-party vehicle fleet, etc.). For example, the autonomous vehicle service platform 302 can facilitate the generation of service assignments (e.g., indicative of the vehicle service type, origin location, destination location, and/or other parameters) to be performed by vehicles (e.g., within a fleet) in response to requests for vehicle services (e.g., from a user).

The autonomous vehicle service platform 302 can include integration platform 304 configured to integrate autonomous vehicles (e.g., autonomous computing systems) with the autonomous vehicle service platform 302. In some examples, the integration platform 304 is configured to integrate autonomous vehicles from different systems, such as from different vendors or providers of autonomous vehicles. The integration platform 304 enables multiple third-party systems to be integrated into a single autonomous vehicle service platform 302. Additionally, the integration platform 304 enables autonomous vehicles directly controlled by the operator of the autonomous vehicle service platform 302 to be integrated into a common service with autonomous vehicles from third-party systems.

The vehicle service test system 300 can include one or more vehicle simulation services. A vehicle simulation service can include one or more instances of a simulated autonomous vehicle. For instance, a vehicle simulation service can be provided at the autonomous vehicle service platform 302 as a platform vehicle simulation service 306 in some examples. Additionally and/or alternatively, a vehicle simulation service can be implemented at a computing device (e.g., computing device 314, etc.) remote from the autonomous vehicle service platform as a local vehicle simulation service for example.

In some examples, a platform vehicle simulation service 306 can be implemented at the autonomous vehicle service platform 302, such as at the same set of servers and/or within the same network used to implement the autonomous vehicle service platform 302, for example. Such a platform vehicle simulation service 306 can include one or more instances of a simulated autonomous vehicle. Each instance of the simulated autonomous vehicle can include an interface associated with the integration platform 304. A developer can provide data in association with the instance of the autonomous vehicle and data in association with the vehicle service simulation through the same interface. For example, a developer can access an interface for the simulator to initialize and/or modify a state of the simulated autonomous vehicle instance.

Additionally, the same interface may be used to dispatch, accept, and simulate a vehicle service using the autonomous vehicle instance. In this manner, a developer can use a graphical user interface such as a browser interface rather than a command line interface for controlling an autonomous vehicle instance. The simulator may include a vehicle simulation service client configured to communicate with the platform vehicle simulation service 306. For example, the vehicle simulation service client can communicate with the platform vehicle simulation service 306 to accept vehicle service requests and control the autonomous vehicle instance. A developer can also use the graphical user interface to create a specific scenario, including a plurality of specific steps for an autonomous vehicle to perform a service. The state of the autonomous vehicle instance can be stored and updated in the simulator interface and pushed to the platform vehicle simulation service 306. The platform vehicle simulation service 306 can be stateful and can route calls to the autonomous vehicle instance where the requested autonomous vehicle interface is running.

In some examples, a vehicle simulation service (e.g., platform vehicle simulation service 306) process may communicate with the integration platform 304 and simulation interfaces such as a service-flow simulator interface and/or vehicle simulator interface. In some examples, interfaces may be provided at one or more client computing devices (e.g., computing device 314, etc.). The vehicle simulation service process may include one or more endpoints (e.g., RPC endpoints) to facilitate communication with simulation interfaces (e.g., client computing devices using CLI and/or RPC).

The autonomous vehicle service platform 302 can include a service-flow simulator 308 configured as a tool for simulating service-flows using an autonomous vehicle. The vehicle service test system 300 can obtain data indicative of one or more parameters for at least one vehicle service simulation. The parameters for a vehicle service simulation may include parameters that define a vehicle service-flow. For example, data defining a vehicle service-flow may define a dispatch of a vehicle service to an instance of a simulated autonomous vehicle. Data defining the vehicle service-flow may also include data instructing the instance of the simulated autonomous vehicle to accept or reject the service request. The data may additionally include data indicative of service-flow updates and/or location updates. The data may indicate a route from a pick-up location to a drop-off location in example embodiments.

The autonomous vehicle service platform 302 can include a real-time interface 310 provided between the integration platform 304 and the service-flow simulator 308. A service request can be provided from the service-flow simulator 308 through the real-time interface 310 to the integration platform 304.

The autonomous vehicle service platform 302 can include a service-flow updater 312 that passes service-flow updates to and from the integration platform 304. Service-flow updates can be received at the integration platform 304 as a push notification from the service-flow updater 312. An update can be passed to the instance of the simulated autonomous vehicle corresponding to the service request. For example, an interface (e.g., SDK) inside the autonomous vehicle instance can establish a consistent connection (e.g., HTTP2) with the integration platform 304. A service request can be matched with the instance of the autonomous vehicle using a flag or other suitable identifier.

The vehicle service test system 300 can include one or more testing libraries 316 that can interface with the vehicle service test system 300 to provide for programmatically developing testing scenarios for running autonomous vehicle service simulations. For example, a developer can incorporate one or more testing libraries (e.g., a testing library 316) into code to programmatically control a test autonomous vehicle and/or vehicle service.

A testing library 316 can be used to interface with one or more simulation services and/or interface directly with an integration platform (e.g., integration platform 304). For example, one or more testing libraries (e.g., a testing library 316) may be used to interface with the autonomous vehicle service platform 302. In some examples, the vehicle service test system 300 may obtain data indicative of one or more parameters for at least one vehicle service simulation using one or more testing libraries (e.g., testing library 316). In some examples, service requests can be programmatically simulated via one or more testing libraries (e.g., testing library 316).

Instance(s) of a simulated autonomous vehicle can be deployed as a network service in some examples, such as at one or more servers in direct communication with the vehicle service test system 300. In other examples, the instances of the simulated autonomous vehicle can be deployed at a local computing device (e.g., computing device 314) remote from the vehicle service test system 300. The local computing device can be operated by the same entity that operates an autonomous vehicle service platform, or by a third-party entity. In either case, the vehicle service test system can communicate with the simulated autonomous vehicle instances using various communication protocols. In some examples, each instance of a simulated autonomous vehicle may include an interface such as an interface programmed in a software development kit (SDK) that is similar to or the same as an interface (e.g., SDK) included within an actual autonomous vehicle used to provide the vehicle service. The interface may enable the vehicle service test system to issue instructions to the autonomous vehicle instance to accept a service request, reject a service request, update the pose field of the autonomous vehicle instance, etc. In some examples, a user may deploy instances of a simulated autonomous vehicle using one or more test libraries (e.g., testing library 316).

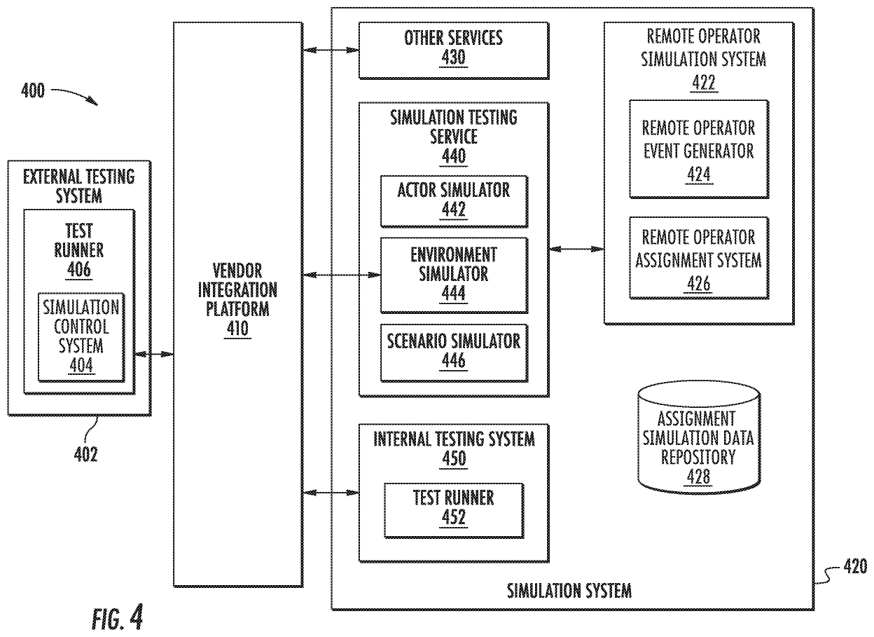

FIG. 4 depicts an example entity infrastructure 400 according to example embodiments of the present disclosure. The entity infrastructure includes an external testing system 402, a vendor integration platform 410, and a simulation system 420. In some examples, the vendor integration platform 410 can be integrated into the simulation system 420. In other examples, the vendor integration platform 410 can be distinct from the simulation system 420 and will thus communicate to the simulation system 420 via a communication network. The external testing system 402 can be a computing system associated with a third-party entity and can communicate with the vendor integration platform 410 via a communication network.

The external testing system 402 can include a simulation control system 404 and a test runner 406. The external testing system 402 can transmit one or more API calls (e.g., requests to perform an action at the simulation system 420 via an API available to the external testing system 402). The external testing system 402 can communicate any API calls to the vendor integration platform 410 which is a public-facing interface that allows external systems (third-party systems that are authorized) to submit requests and receive the results from the simulation system 420. In some examples, the external testing system 402 can also simulate some or all of the simulation autonomous vehicle and its actions and transmit data describing the simulated autonomous vehicle to the simulation testing service 440 via the vendor integration platform 410.

Specifically, the test runner 406 can send and receive data associated with a simulation to the simulation system 420 via the vendor integration platform 410. The test runner 406 can, in response to user input, transmit a request to initiate a simulation at the simulation system 420. In some examples, the test runner 406 can submit information associated with initiating a simulation, including, but not limited to, a selected scenario, information describing the autonomous vehicle to be tested, data associated with the simulation (e.g., the simulated location), and so on.

The simulation control system 404 can allow a user to interact with the simulation to generate events or simulate an actor within the simulation. For example, a user associated with a third party can, as part of a scenario, direct the simulation system 420 to generate particular events, generate particular actions for one or more actors, and so on. The simulation control system 404 can also provide information to simulate an autonomous vehicle. Thus, the autonomous vehicle can partially or wholly be simulated at the external testing system 402 and interact with the simulation system 420 via the vendor integration platform 410.

The vendor integration platform 410 can be a self-driving platform gateway that receives communication from all autonomous vehicles that provide services for the service entity. The vendor integration platform 410 can include provide APIs that allow external systems to submit requests to, and receive responses from, the simulation system 420. The vendor integration platform 410 can validate requests before passing the requests to the simulation system 420 to ensure that all requests meet the requirements of the simulation system 420.

The simulation system 420 includes a simulation testing service 440, an internal testing system 450, other services system 430 for providing miscellaneous other services, and a remote operator simulation system 422. The internal testing system 450 includes a test runner 452 that is used for initiating, controlling, monitoring, and analyzing the results of a simulation run by the simulation system 420. Internal testers (e.g., users associated with the service entity) can avoid sending requests to the vendor integration platform 410. Instead, internal testers can use the test runner 452 to request that a simulation be initiated directly by interacting with the simulation testing service 440. The test runner 452 also allows testers to identify the specific autonomous vehicle that is to be simulated and provide parameters for the simulation, including but not limited to the location of the simulation, the number of simulated actors and their characteristics, the number and type of remote operators to be simulated, a specific scenario to be tested, and any specific events or variables to be generated.

While a simulation is being performed, a user can use the test runner 452 to monitor the simulation, provide input needed for specific events, and make on-the-fly alterations to the simulation or scenario as needed. The simulation system 420 can provide data representing the current state of the simulation (e.g., text, audio, or video) to the internal testing system 450 for a tester to view, as needed.

The simulation testing service 440 can include an actor simulator 442, an environment simulator 444, and a scenario simulator 446. The actor simulator 442 can simulate one or more actors within the simulation. For example, if a rider is needed to simulate a particular scenario, the actor simulator 442 can programmatically generate events as needed based on predefined scenario data. For example, if the predefined scenario data includes a rider submitting a ride request, the actor simulator 442 can automatically generate that event or cause the event to be generated at a time dictated by the predefined scenario. In some examples, the actor simulator 442 can interface with the remote operator simulation system 422 to receive events and other information associated with one or more simulated remote operators. In addition, the simulation testing service 440 can transmit information about the simulation (including requests for remote operator assistance) to the remote operator simulation system 422.

In other examples, the actor simulator 442 can include an API that allows users (either external users from the external testing system 402 or internal users from the internal testing system 450) to request specific events to be generated for the simulation. For example, a user can specify that a specific event (e.g., successful drop-off of a rider) be generated at a particular time to test how the simulated autonomous vehicle will respond. In this way, a user can fully control and/or customize the specific situations that are tested by the simulation system 420.

An environment simulator 444 can generate a simulation sandbox in which the simulated autonomous vehicle is tested. The simulation sandbox can include a location that is being simulated, one or more other simulated entities within the sandbox (e.g., pedestrians, other vehicles, and so on), and static parts of the simulated environment (e.g., buildings, roads, signs, and so on). The environment simulator 444 can simulate an autonomous vehicle moving through that environment including simulating any needed physics, the actions of one or more other users, and so on. Thus, the sandbox can simulate the experience of an autonomous vehicle moving through an actual live environment.

A scenario simulator 446 can simulate one or more steps (or states) of a selected predefined scenario. Specifically, the scenario simulator can receive scenario data from the remote operator event generator 424. The scenario data can include data describing a series of steps (or states) to be performed to complete the scenario and a set of events associated with each step. The scenario simulator 446 can ensure that any events that are required to be generated by the simulation system (e.g., simulating riders or other actors in the environment) are generated in a timely manner. Similarly, the scenario simulator 446 can monitor the simulated autonomous vehicle to ensure that the simulated autonomous vehicle is generating the correct events at the correct times. For example, once a simulated autonomous vehicle receives a rider request, the simulated autonomous vehicle can be expected to generate a request acceptance action and then begin navigating to the pick-up point. The scenario simulator 446 can, in response to determining that the expected events have been generated and/or received, move the scenario from a first state or step to a second state or step. The scenario simulator 446 can continue to monitor the scenario until the scenario reaches an end state (e.g., either a failure state or a completion state). The other services system 430 can provide a series of other services required by the simulation system 420, such as an internal actor simulator that serves to generate events for simulated riders and other actors in the environment.

A remote operator simulation system 422 can include a remote operator event generator 424, a remote operator assignment system 426, and an assignment simulation data repository 428. In some examples, the assignment simulation data repository 428 stores data associated with a plurality of potential simulations that may be performed by the simulation system 420. When a simulation begins, the simulation system 420 can receive, in a request from a user, a selection of a particular assignment and/or simulation. The remote operator simulation system 422 can generate one or more simulated remote assistance operators. The number and type of simulated remote assistance operators can be determined, at least in part, based on the selected assignment or scenario. In some examples, data describing the number and type of simulated remote assistance operators can be stored in the assignment simulation data repository 428.

In some examples, the remote operator simulation system can simulate the actions and responses of the simulated remote operators as needed during a particular simulation, scenario, or assignment. For example, a given assignment can include one or more states in which the simulation system 420 requires a remote operator to take an action before the simulation can move forward to the next state. In these scenarios, the remote operator simulation system can, based on information received from the simulation testing service 440 (such as a request for remote assistance from a simulated autonomous vehicle or a prompt to provide an event from the scenario simulator 446), generate one or more events as part of a simulation. In some examples, the specific events generated by one or more simulated remote operators can be determined by a user running the simulation (e.g., either an internal user communicating through the internal testing system 450 or an external (or third-party) user communicating from the external testing system 402 via the vendor integration platform 410.

In other examples, the events generated by the simulated remote operator can be determined automatically, without user input, based on predetermined simulation data or data associated with the scenario or assignment. If the specific scenario being simulated is a scenario in which a rider is transported from one location to another location, a simulated remote operator may generate one or more events as part of the process. For example, a simulated remote operator can generate a cabin check event (e.g., either determining that the cabin of an autonomous vehicle is prepared for a rider or is not prepared for a rider) and transmit the results of the cabin check event to the simulated autonomous vehicle.

In some examples, the remote operator event generator 424 can generate the events associated with the simulated remote operators. The simulation testing service 440 can transmit state data to the remote operator simulation system indicating the specific state of the simulation, the events expected in the current state, and any data necessary to generate an appropriate event. Using this state data, in addition to any data retrieved from the assignment simulation data repository 428, the remote operator event generator 424 can generate an appropriate event and transmit it to the simulation testing service 440.

In some examples, the remote operator event generator 424 can assign each event to a particular simulated remote operator. For example, each simulated remote operator can have an associated remote operator event generator or a dedicated portion of the remote operator event generator 424. Thus, if a given simulation includes more than one simulated remote operator, one or more remote operator event generators 424 can assign each generated event with a particular simulated remote operator.

In some examples, the remote operator assignment system 426 can determine which simulated remote operator, from a plurality of simulated remote operators, to assign to a particular simulated process and/or request. For example, the simulated remote operators can have one or more operator parameters, including operator location, operator history, operator training, and/or one or more parameters associated with the autonomous vehicle, including, but not limited to the geographic location of the autonomous vehicle, the make of the autonomous vehicle, the fleet operator of the autonomous vehicle, and so on. The remote operator assignment system 426 can receive instructions from a user to determine which simulated remote operator to assign to particular requests from a simulated autonomous vehicle.

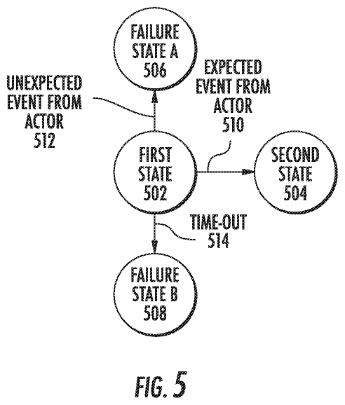

FIG. 5 depicts a state machine diagram according to example embodiments of the present disclosure. In this example, the scenario or simulation is in a first state 502. Note that this may not be the initial state of a multi-state directed graph. While in the first state 502, a component of the simulation system (e.g., the simulation system 420 of FIG. 4) can monitor the simulation for events. If an expected event 510 is received from an actor (e.g., a simulated autonomous vehicle or simulated remote assistance operator), the scenario can move from the first state 502 to a second state 504 along a directed edge.

If an unexpected event 512 is received from the actor (e.g., the simulated autonomous vehicle unexpectedly drives to the wrong address or turns down a ride offer that it should have accepted), the scenario can move from the first state 502 to a failure state (in this case failure state A 506). In some examples, moving into a failure state requires intervention from a simulated actor or input from the user directing the simulation. Moving into a failure state can cause the simulation of the predefined scenario to end. Once the predefined scenario has ended, the simulation system (e.g., the simulation system 420 of FIG. 4) can store or transmit data describing the simulation such that further analysis can be performed.

In some examples, a time limit can be associated with a particular state. Thus, if no event is received within the time limit, the system determines that the actor (e.g., the simulated autonomous vehicle) has timed-out 514 and the scenario enters a failure state (in this case failure state B 508). The failure states can be distinct so that the specific reason for entering a failure state can be quickly and easily determined by a reviewing user.

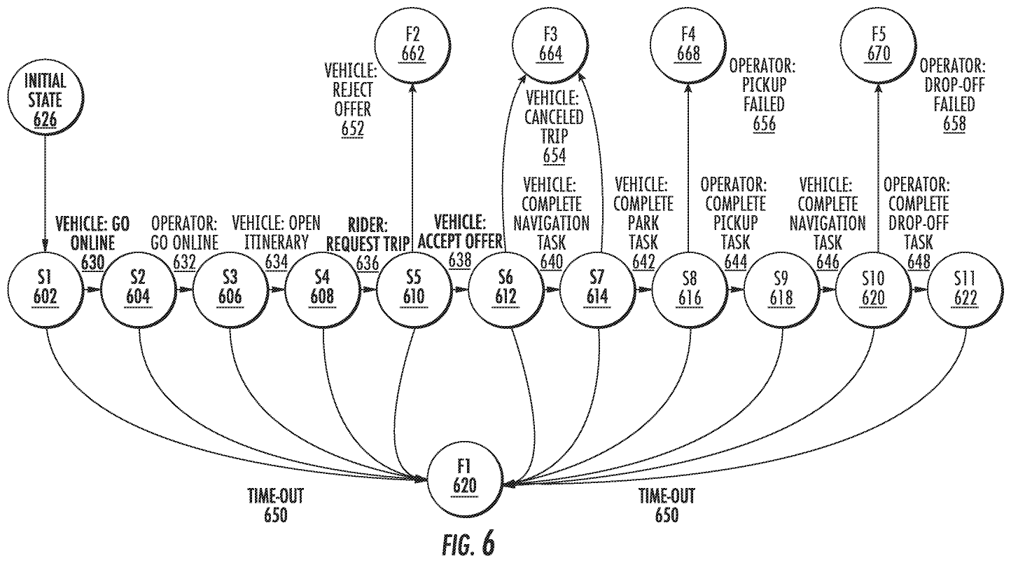

FIG. 6 depicts a state machine flow diagram according to example embodiments of the present disclosure. In this example, the state machine flow diagram represents a directed graph for the “rider request” scenario. As noted above, the directed graph is a series of nodes connected by edges. Each node represents a state in the predefined scenario and each edge represents a particular event that causes the state machine to move from one state to another.

The initial state 626 represents the initial state of the scenario when it begins. The simulation system (e.g., the simulation system 420 in FIG. 4) automatically moves to S1 602, the first state in the rider request scenario. Each state can include a time limit that represents an amount of time before the scenario simulation system (e.g., the simulation system 420 in FIG. 4) determines that the simulated autonomous vehicle has timed out 650 and enters the F1 failure state 660. The specific time limit can vary based on the current state and the simulated autonomous vehicle.

While in the S1 state 602, the simulation system (e.g., the simulation system 420 in FIG. 4) can monitor for events generated by the simulated autonomous vehicle. Once the simulated autonomous vehicle has performed any preparation tasks, the simulated autonomous vehicle can generate a “go online” event 630. In response, the simulation system (e.g., the simulation system 420 in FIG. 4) can move the scenario from the S1 state 602 to the S2 state 604. Once the simulated autonomous vehicle has generated the “go online” event 630, the simulation system (e.g., the simulation system 420 in FIG. 4) can transmit a notification (or request) to the remote operator simulation system (e.g., remote operator simulation system 422 in FIG. 4). In response, the remote operator simulation system (e.g., the remote operator simulation system 422 in FIG. 4) can generate one or more simulated remote operators. Once the one or more simulated remote operators have been generated, the (e.g., remote operator simulation system 422 in FIG. 4) can generate a “go online” event 632. Once the remote operator “go online” event 632 has been generated, the scenario can be moved from state S2 604 to state S3 606.

While in the state S3 606, the simulated autonomous vehicle can generate an “open itinerary” event 634 once the simulated autonomous vehicle is prepared to receive rider requests. The simulation system (e.g., the simulation system 420 in FIG. 4) can, in response to receiving the “open itinerary” event 632, move the scenario from the state S3 606 to the state S4 608. Once the scenario has reached the state S4 608, the simulation system (e.g., the simulation system 420 in FIG. 4) can cause a simulated rider to generate a request trip event 636. The user can designate one or more trip characteristics including the origin location and destination location.

Once the request trip event 636 has been generated, the simulation system (e.g., the simulation system 420 in FIG. 4) can move the scenario from the state S4 608 to the state S5 610. In response to a request trip event 636, a simulated autonomous vehicle can either accept the offered trip or reject the offered trip. If the simulated autonomous vehicle generates a “reject offer” event 652, the scenario can move into the F2 failure state 662. The F2 failure state 662 indicates that the simulated autonomous vehicle has unexpectedly rejected an offered trip. The scenario and/or simulation can then be terminated.

If the simulated autonomous vehicle generates an accept offer event 638, the scenario simulation system can move the scenario from state S5 610 to state S6 612. In some examples, while in state S6 612, the simulated autonomous vehicle can simulate navigating from the current location of the autonomous vehicle to the origin location of the rider request. When the simulated autonomous vehicle reaches the origin location, the simulated autonomous vehicle can generate a “complete navigation task” event 640, wherein the “complete navigation task” event 640 indicates that the autonomous vehicle has reached the origin location and is preparing to park. The simulation system (e.g., the simulation system 420 in FIG. 4) can generate a notification to the simulated rider indicating the arrival of the simulated autonomous vehicle. Once the “complete navigation task” event 640 has been received, the simulation can move from state S6 612 to state S7 614.

In some examples, the simulated autonomous vehicle may not be able to reach the origin location. For example, if the simulated autonomous vehicle is unable to locate the origin location or the path to the origin location is blocked and no alternate route is available. In this case, the simulated autonomous vehicle can generate a “canceled trip” event 654. If the simulated autonomous vehicle generates a “canceled trip” event 654, the scenario can move into the F3 failure state 664. In some examples, the “canceled trip” event 654 can be generated in response to determining that the rider has canceled the trip or that the service itself has canceled the trip.

Once in state S7 614, the simulated autonomous vehicle can attempt to park. Once the simulated autonomous vehicle has successfully parked (within the simulation), the simulated autonomous vehicle can generate a “complete park task” event 642. The simulation can move the scenario from state S7 614 to state S8 616 in response to receiving the “complete park task” event 642. The simulated autonomous vehicle can generate a “canceled trip” event 654 if it was unable to successfully park and move into failure state F3 664.

Once in state S8 616, the simulation system (e.g., the simulation system 420 in FIG. 4) can simulate a rider entering the simulated autonomous vehicle. In addition, the simulation system (e.g., the simulation system 420 in FIG. 4) can request that a simulated remote operator perform a cabin check. In some examples, performing a cabin check includes determining, based on sensor data from the interior of the cabin, whether the rider has successfully entered the simulated autonomous vehicle. If the simulated remote operator determines that the rider has successfully entered the simulated autonomous vehicle, the simulated remote operator can generate a “complete pickup task” event 644. Once the “complete pickup task” event 644 has been received, the simulation can move from state S8 616 to state S9 618.

If the simulated remote operator determines that the rider has not successfully entered the autonomous vehicle, the simulated remote operator can generate a “pickup failed” event 656 and cause the scenario to enter state F4 668. It should be noted that the simulation may not actually analyze simulated sensor data to determine whether to generate a “complete pickup task” event 644 or a “pickup failed” event 656. Instead, the events may be generated programmatically based on the simulation specifications or generated by a user controlling the simulation.

Once in state S9 618, the simulation system (e.g., the simulation system 420 in FIG. 4) can simulate the simulated autonomous vehicle traveling from the origin location to a destination location. Once the simulated autonomous vehicle reaches the destination location, the simulated autonomous vehicle can generate a “complete navigation task” event 646, wherein the “complete navigation task” event 646 indicates that the autonomous vehicle has reached the destination location and is preparing to drop off the rider. Once the “complete navigation task” event 646 has been received, the simulation can move from state S9 618 to state S10 620.

Once in state S10 620, the simulation system (e.g., the simulation system 420 in FIG. 4) can simulate the dropping of the rider at the destination location. In addition, the simulation system (e.g., the simulation system 420 in FIG. 4) can request that a simulated remote operator perform a cabin check. If the simulated remote operator determines that the rider has successfully been dropped-off, the simulated remote operator can generate a “complete drop-off task” event 648. Once the “complete drop-off task” event 648 has been received, the simulation can move from state S10 620 to state S11 622. State S11 622 represents successful completion of the assignment (or scenario).

If the simulated remote operator determines that the rider has not successfully entered the autonomous vehicle, the simulated remote operator can generate a “drop-off failed” event 658 and cause the scenario to enter failure state F5 670.

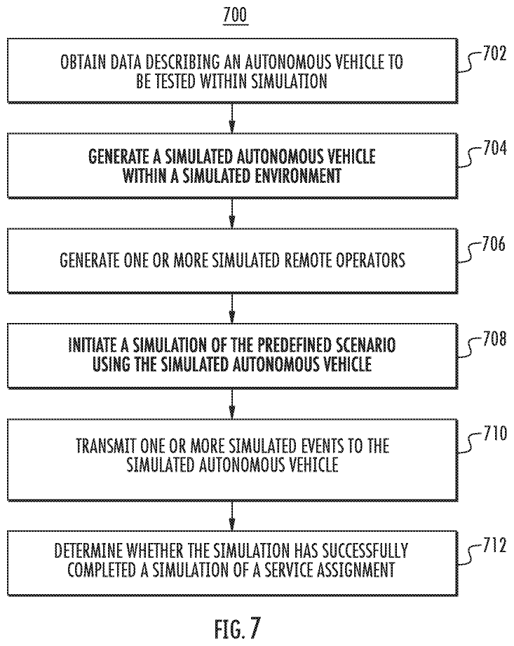

FIG. 7 depicts a flow diagram of an example method for enabling the use of simulated remote operators according to example embodiments of the present disclosure. One or more portion(s) of the method 700 can be implemented by one or more computing devices such as, for example, the computing devices described herein. Moreover, one or more portion(s) of the method 700 can be implemented as an algorithm on the hardware components of the device(s) described herein to. FIG. 7 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure.

In some embodiments, a simulation system (e.g., the simulation system 420 in FIG. 4) can obtain, at 702, data associated with a simulated autonomous vehicle to use within a simulation environment based at least in part on a service assignment. In some examples, the data associated with a simulated autonomous vehicle can be data that describes the autonomous vehicle that is to be simulated. In other examples, the autonomous vehicle is simulated at a remote system and information about the simulated autonomous vehicle can be transmitted to the simulation system (e.g., the simulation system 420 in FIG. 4) as needed.

In some examples, the service assignment can include a plurality of states, each state representing a step in a process associated with the service assignment. In some examples, a state in the plurality of states is associated with one or more events. For example, if the state is a simulated autonomous vehicle traveling to a particular location, the state may be associated with an event representing the location being transmitted to the simulated autonomous vehicle (e.g., to initiate the state) and a notification from the simulated autonomous vehicle that the simulated autonomous vehicle has reached the location (e.g., to move to another state).

In some examples, the simulation environment can be a sandbox that is configured to isolate the simulation from a real-world service assignment allocation by the service entity. In some examples, the service assignment is defined based, at least in part, on service assignment data received from a third party. In some example implementations, the service assignment is a pre-defined scenario.

In some embodiments, a simulation system (e.g., the simulation system 420 in FIG. 4) can generate, at 704, one or more simulated remote assistance operators. In some examples, the simulate remote assistance operators can generate events in response to the simulated service assignment, either programmatically or in response to user input.

In some embodiments, a simulation system (e.g., the simulation system 420 in FIG. 4) can initiate, at 706, a simulation of a service assignment using the data associated with the simulated autonomous vehicle to perform the service assignment within the simulation environment, wherein upon initiation an initial state of the service assignment is assigned to be a current state of the simulation. After initiating the simulation of the service assignment, the simulation system (e.g., the simulation system 420 in FIG. 4) can determine whether the current state in the plurality of states is associated with an event that is expected to be received from a simulated remote assistance operator in the one or more simulated remote assistance operators.

In response to determining that the current state is associated with the event that is expected to be received from the simulated remote assistance operator, the simulation system (e.g., the simulation system 420 in FIG. 4) can direct the simulated remote assistance operator to generate a simulated event associated with the event that is expected to be received.

In some example embodiments, the simulation system (e.g., the simulation system 420 in FIG. 4) can provide, at 708, one or more simulated events from the one or more simulated remote assistance operators to the simulated autonomous vehicle, the one or more simulated events being associated with the service assignment and causing the current state of the simulation to transition from a first state of the service assignment to a second state of the service assignment.

The simulation system (e.g., the simulation system 420 in FIG. 4) can determine whether the simulated autonomous vehicle has successfully responded to the simulated event. In some examples, the simulation can include a plurality of simulated remote assistance operators. The simulation system (e.g., the simulation system 420 in FIG. 4) can determine that a current state in the plurality of states is associated with a simulated event generated by a simulated remote assistance operator. In response to determining that the current state in the plurality of states is associated with the simulated event generated by the simulated remote assistance operator, the simulation system (e.g., the simulation system 420 in FIG. 4) can select a particular simulated remote assistance operator from the plurality of simulated remote assistance operators. The simulation system (e.g., the simulation system 420 in FIG. 4) can assign the particular simulated remote assistance operator to generate the simulated event associated with the current state.

In some examples, the particular simulated remote assistance operator can be selected from the plurality of simulated remote assistance operators based, at least in part, on one or more simulated operator attributes and one or more simulated event parameters. The service assignment can be a ride request and the simulated event is a cabin check event. The service assignment can be a ride request and the simulated event is a rider exit confirmation event.

In some examples, one or more simulated events can be generated in response to user input. The one or more simulated events can be generated automatically based, at least in part, on predefined test data. While simulating the service assignment, the simulation system (e.g., the simulation system 420 in FIG. 4) can determine whether one or more criteria have been met. Responsive to determining that the one or more criteria have been met, the simulation system (e.g., the simulation system 420 in FIG. 4) can initiate a remote assistance session.

In some example embodiments, the simulation system (e.g., the simulation system 420 in FIG. 4) can determine whether the simulated autonomous vehicle has successfully completed the service assignment based at least in part on the current state of the simulation.

Various means can be configured to perform the methods and processes described herein. For example, FIG. 8 depicts a diagram of an example computing system that can include data obtaining unit(s) 802, remote operator generation unit(s) 804, simulation unit(s) 806, event generation unit(s) 808, scenario evaluation unit(s) 810, and/or other means for performing the operations and functions described herein. In some implementations, one or more of the units may be implemented separately. In some implementations, one or more units may be a part of or included in one or more other units. These means can include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The means can also, or alternately, include software control means implemented with a processor or logic circuitry for example. The means can include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware.

The means can be configured to perform one or more algorithm(s) for carrying out the operations and functions described herein. For instance, the means can be configured to obtain data associated with a simulated autonomous vehicle to use within a simulation environment based at least in part on a service assignment. For example, a simulation system can receive information describing the characteristics and actions of simulated autonomous vehicle. A data obtaining unit 802 is one example of a means for obtaining data associated with a simulated autonomous vehicle to use within a simulation environment based at least in part on a service assignment as described herein.

The means can be configured to generate, by the computing system, one or more simulated remote assistance operators. For example, the simulation system can, using the data associated with a simulated autonomous vehicle as well as data associated with the service assignment, generate one or more simulated remote assistance operators. A remote operator generation unit 804 is one example of a means for generating one or more simulated remote assistance operators as described herein.

The means can be configured to initiate a simulation of a service assignment using the data associated with the simulated autonomous vehicle to perform the service assignment within the simulation environment, wherein upon initiation an initial state of the service assignment is assigned to be a current state of the simulation. For example, the system can generate a simulated environment and, based on information associated with the service assignment, generate the conditions and events necessary to simulate the service assignment. A simulation unit 806 is one example of a means for initiating a simulation of a service assignment using the data associated with the simulated autonomous vehicle to perform the service assignment within the simulation environment, wherein upon initiation an initial state of the service assignment is assigned to be a current state of the simulation.

The means can be configured to provide one or more simulated events from the one or more simulated remote assistance operators to the simulated autonomous vehicle, the one or more simulated events being associated with the service assignment and causing the current state of the simulation to transition from a first state of the service assignment to a second state of the service assignment. For example, the simulated system can generate events for a simulated remote operator as directed by a user or as determined by data associated with the service assignment. An event generation unit 808 is one example of a means for providing one or more simulated events from the one or more simulated remote assistance operators to the simulated autonomous vehicle, the one or more simulated events being associated with the service assignment and causing the current state of the simulation to transition from a first state of the service assignment to a second state of the service assignment.

The means can be configured to determine whether the simulated autonomous vehicle has successfully completed the service assignment based at least in part on the current state of the simulation. For example, if the system determines that the scenario has reached an end state, the system can determine whether that end state is a success state or a failure state. A scenario evaluation unit 810 is one example of a means for determining whether the simulated autonomous vehicle has successfully completed the service assignment based at least in part on the current state of the simulation.

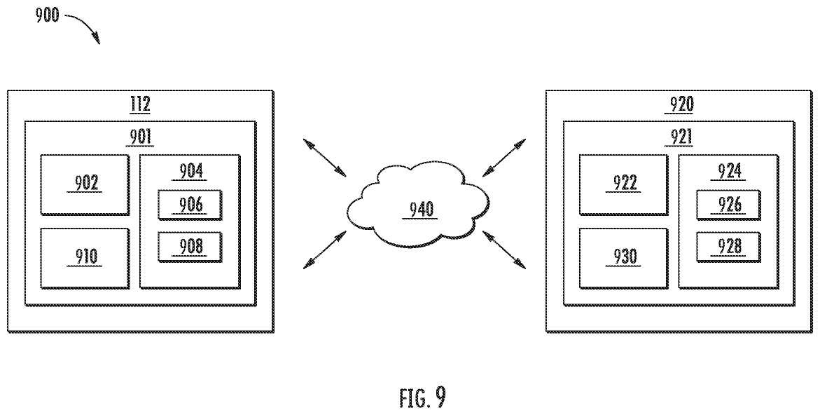

FIG. 9 depicts a block diagram of an example computing system 900 according to example embodiments of the present disclosure. The example system 900 illustrated in FIG. 9 is provided as an example only. The components, systems, connections, and/or other aspects illustrated in FIG. 9 are optional and are provided as examples of what is possible, but not required, to implement the present disclosure. As one example, the example system 900 can include the vehicle computing system 112 of the autonomous vehicle 102 and a remote computing system 920 (e.g., operations computing system, other computing system, etc. that is remote from the vehicle computing system 112) that can be communicatively coupled to one another over one or more network(s) 940. The remote computing system 920 can be and/or include the operations computing system 104 and/or remote computing devices 106 of FIG. 1, as an example. The remote computing system 920 can be associated with a central operations system and/or an entity associated with the vehicle 102 such as, for example, a vehicle owner, vehicle manager, fleet operator, service provider, etc. For instance, the remote computing system 920 can be or otherwise include the operations computing system 104 described herein.

The computing device(s) 901 of the vehicle computing system 112 can include processor(s) 902 and at least one memory 904. The one or more processors 902 can be any suitable processing device (e.g., a processor core, a microprocessor, an ASIC, a FPGA, a controller, a microcontroller, etc.) and can be one processor or a plurality of processors that are operatively connected. The memory 904 can include one or more non-transitory computer-readable storage media, such as RAM, ROM, EEPROM, EPROM, one or more memory devices, flash memory devices, magnetic disks, data registers, etc., and combinations thereof.

The memory 904 can store information that can be accessed by the one or more processors 902. For instance, the memory 904 (e.g., one or more non-transitory computer-readable storage mediums, memory devices) can include computer-readable instructions 906 that can be executed by the one or more processors 902. The instructions 906 can be software written in any suitable programming language or can be implemented in hardware. Additionally, or alternatively, the instructions 906 can be executed in logically and/or virtually separate threads on processor(s) 902.

For example, the memory 904 on-board the vehicle 102 can store instructions 906 that when executed by the one or more processors 902 cause the one or more processors 902 (e.g., in the vehicle computing system 112) to perform operations such as any of the operations and functions of the computing device(s) 901 and/or vehicle computing system 112, any of the operations and functions for which the vehicle computing system 112 is configured, and/or any other operations and functions described herein.

The memory 904 can store data 908 that can be obtained (e.g., received, accessed, written, manipulated, created, generated, etc.) and/or stored. The data 908 can include, for instance, services data (e.g., assignment data, route data, user data, etc.), sensor data, map data, perception data, prediction data, motion planning data, object states and/or state data, service assignment data, and/or other data/information as described herein. In some implementations, the computing device(s) 901 can obtain data from one or more memories that are remote from the autonomous vehicle 102.

The computing device(s) 901 can also include a communication interface 910 used to communicate with one or more other system(s) (e.g., the remote computing system 920). The communication interface 910 can include any circuits, components, software, etc. for communicating via one or more networks (e.g., network(s) 940). In some implementations, the communication interface 910 can include, for example, one or more of a communications controller, receiver, transceiver, transmitter, port, conductors, software, and/or hardware for communicating data.

The remote computing system 920 can include one or more computing device(s) 921. The computing device(s) 921 can include one or more processors 922 and at least one memory 924. The one or more processors 922 can be any suitable processing device (e.g., a processor core, a microprocessor, an ASIC, a FPGA, a controller, a microcontroller, etc.) and can be one processor or a plurality of processors that are operatively connected. The memory 924 can include one or more tangible, non-transitory computer-readable storage media, such as RAM, ROM, EEPROM, EPROM, one or more memory devices, flash memory devices, data registers, etc., and combinations thereof.

The memory 924 can store information that can be accessed by the one or more processors 922. For instance, the memory 924 (e.g., one or more tangible, non-transitory computer-readable storage media, one or more memory devices, etc.) can include computer-readable instructions 926 that can be executed by the one or more processors 922. The instructions 926 can be software written in any suitable programming language or can be implemented in hardware. Additionally, or alternatively, the instructions 926 can be executed in logically and/or virtually separate threads on processor(s) 922.

For example, the memory 924 can store instructions 926 that when executed by the one or more processors 922 cause the one or more processors 922 to perform operations such as any of the operations and functions of the operations computing system 104, the remote computing devices 106, the remote computing system 920 and/or computing device(s) 921 or for which any of these computing systems are configured, as described herein, and/or any other operations and functions described herein.

The memory 924 can store data 928 that can be obtained and/or stored. The data 928 can include, for instance, services data (e.g., assignment data, route data, user data etc.), data associated with autonomous vehicles (e.g., vehicle data, maintenance data, ownership data, sensor data, map data, perception data, prediction data, motion planning data, object states and/or state data, service assignment data, etc.), third-party entity data, inventory data, scheduling data, log data, attribute data, scenario data, simulation data (e.g., simulation control data, simulation result data, etc.), testing data, training data, integration data, libraries, user data, and/or other data/information as described herein. In some implementations, the computing device(s) 921 can obtain data from one or more memories that are remote from the remote computing system 920.

The computing device(s) 921 can also include a communication interface 930 used to communicate with one or more other system(s) (e.g., the vehicle computing system 112, remote computing systems, etc.). The communication interface 930 can include any circuits, components, software, etc. for communicating via one or more networks (e.g., network(s) 940). In some implementations, the communication interface 930 can include, for example, one or more of a communications controller, receiver, transceiver, transmitter, port, conductors, software, and/or hardware for communicating data.

The network(s) 940 can be any type of network or combination of networks that allows for communication between devices. In some embodiments, the network(s) 940 can include one or more of a local area network, wide area network, the Internet, secure network, cellular network, mesh network, peer-to-peer communication link, and/or some combination thereof, and can include any number of wired or wireless links. Communication over the network(s) 940 can be accomplished, for instance, via a communication interface using any type of protocol, protection scheme, encoding, format, packaging, etc.

Computing tasks discussed herein as being performed at computing device(s) remote from the autonomous vehicle can instead be performed at the autonomous vehicle (e.g., via the vehicle computing system), or vice versa. Such configurations can be implemented without deviating from the scope of the present disclosure. The use of computer-based systems allows for a great variety of possible configurations, combinations, and divisions of tasks and functionality between and among components. Computer-implemented operations can be performed on a single component or across multiple components. Computer-implements tasks and/or operations can be performed sequentially or in parallel. Data and instructions can be stored in a single memory device or across multiple memory devices.

Aspects of the disclosure have been described in terms of illustrative embodiments thereof. Numerous other embodiments, modifications, and/or variations within the scope and spirit of the appended claims can occur to persons of ordinary skill in the art from a review of this disclosure. Any and all features in the following claims can be combined and/or rearranged in any way possible.

While the present subject matter has been described in detail with respect to various specific example embodiments thereof, each example is provided by way of explanation, not limitation of the disclosure. Those skilled in the art, upon attaining an understanding of the foregoing, can readily produce alterations to, variations of, and/or equivalents to such embodiments. Accordingly, the subject disclosure does not preclude inclusion of such modifications, variations, and/or additions to the present subject matter as would be readily apparent to one of ordinary skill in the art. For instance, features illustrated and/or described as part of one embodiment can be used with another embodiment to yield a still further embodiment. Thus, it is intended that the present disclosure cover such alterations, variations, and/or equivalents.

What is claimed is:

1. A computer-implemented method for autonomous vehicle service assignment simulation, the method comprising:
obtaining, by a computing system comprising one or more computing devices, data associated with a simulated autonomous vehicle to use within a simulation environment based at least in part on a service assignment;
generating, by the computing system, one or more simulated remote assistance operators;
initiating, by the computing system, a simulation of a service assignment using the data associated with the simulated autonomous vehicle to perform the service assignment within the simulation environment, wherein upon initiation an initial state of the service assignment is assigned to be a current state of the simulation;
providing, by the computing system, one or more simulated events from the one or more simulated remote assistance operators to the simulated autonomous vehicle, the one or more simulated events being associated with the service assignment and causing the current state of the simulation to transition from a first state of the service assignment to a second state of the service assignment; and
determining, by the computing system, whether the simulated autonomous vehicle has successfully completed the service assignment based at least in part on the current state of the simulation.

2. The computer-implemented method of claim 1, wherein the service assignment includes a plurality of states, each state representing a step in a process associated with the service assignment.

3. The computer-implemented method of claim 2, wherein a state in the plurality of states is associated with one or more events.

4. The computer-implemented method of claim 3, further comprising:
after initiating the simulation of the service assignment:
determining, by the computing system, whether the current state in the plurality of states is associated with an event that is expected to be received from a simulated remote assistance operator in the one or more simulated remote assistance operators; and
in response to determining that the current state is associated with the event that is expected to be received from the simulated remote assistance operator, directing, by the computing system, the simulated remote assistance operator to generate a simulated event associated with the event that is expected to be received.

5. The computer-implemented method of claim 4, further comprising:
determining, by the computing system, whether the simulated autonomous vehicle has successfully responded to the simulated event.

6. The computer-implemented method of claim 2, wherein the simulation includes a plurality of simulated remote assistance operators, the method further comprising:
determining, by the computing system, that a current state in the plurality of states is associated with a simulated event generated by a simulated remote assistance operator;
in response to determining that the current state in the plurality of states is associated with the simulated event generated by the simulated remote assistance operator, selecting, by the computing system, a particular simulated remote assistance operator from the plurality of simulated remote assistance operators; and
assigning, by the computing system, the particular simulated remote assistance operator to generate the simulated event associated with the current state.

7. The computer-implemented method of claim 6, wherein the particular simulated remote assistance operator is selected from the plurality of simulated remote assistance operators based, at least in part, on one or more simulated operator attributes and one or more simulated event parameters.

8. The computer-implemented method of claim 1, wherein the service assignment is a ride request and the simulated event is a cabin check event.

9. The computer-implemented method of claim 1, wherein the service assignment is a ride request and the simulated event is a rider exit confirmation event.

10. The computer-implemented method of claim 1, wherein the one or more simulated events are generated in response to user input.

11. The computer-implemented method of claim 1, wherein the one or more simulated events are generated automatically based, at least in part, on predefined test data.

12. The computer-implemented method of claim 1, wherein the simulation environment is a sandbox that is configured to isolate the simulation from a real-world service assignment allocation by a service entity.

13. The computer-implemented method of claim 1, wherein the service assignment is defined based, at least in part, on service assignment data received from a third party.

14. The computer-implemented method of claim 1, wherein the service assignment is a pre-defined scenario.

15. The computer-implemented method of claim 1, the method further comprises:
while simulating the service assignment:
determining, by the computing system, whether one or more criteria have been met; and
responsive to determining that the one or more criteria have been met, initiating, by the computing system, a remote assistance session.

16. A computer system comprising:
one or more processors; and
a memory storing instructions that when executed by the one or more processors cause the computer system to perform operations comprising:
obtaining, by the one or more processors, data associated with a simulated autonomous vehicle to use within a simulation environment based at least in part on a service assignment;
generating, by the one or more processors, one or more simulated remote assistance operators;
initiating, by the one or more processors, a simulation of a service assignment using the data associated with the simulated autonomous vehicle to perform the service assignment within the simulation environment, wherein upon initiation an initial state of the service assignment is assigned to be a current state of the simulation;
providing, by the one or more processors, one or more simulated events from the one or more simulated remote assistance operators to the simulated autonomous vehicle, the one or more simulated events being associated with the service assignment and causing the current state of the simulation to transition from a first state of the service assignment to a second state of the service assignment; and
determining, by the one or more processors, whether the simulated autonomous vehicle has successfully completed the service assignment based at least in part on the current state of the simulation.

17. The computer system of claim 16, wherein the service assignment includes a plurality of states, each state representing a step in a process associated with the service assignment.

18. The computer system of claim 17, wherein one or more expected events are associated with a particular state in the plurality of states.

19. One or more non-transitory computer-readable media comprising instructions that when executed by a computing system comprising one or more computing devices cause the computing system to perform operations comprising:
obtaining data associated with a simulated autonomous vehicle to use within a simulation environment based at least in part on a service assignment;
generating one or more simulated remote assistance operators;
initiating a simulation of a service assignment using the data associated with the simulated autonomous vehicle to perform the service assignment within the simulation environment, wherein upon initiation an initial state of the service assignment is assigned to be a current state of the simulation;
providing one or more simulated events from the one or more simulated remote assistance operators to the simulated autonomous vehicle, the one or more simulated events being associated with the service assignment and causing the current state of the simulation to transition from a first state of the service assignment to a second state of the service assignment; and
determining whether the simulated autonomous vehicle has successfully completed the service assignment based at least in part on the current state of the simulation.

20. The one or more non-transitory computer-readable media of claim 19, wherein the service assignment includes a plurality of states, each state representing a step in a process associated with the service assignment.
